(19) United States
(12) Patent Application Publication
(10) Pub. No.: US 2015/0118487 A1
(43) Pub. Date: Apr. 30, 2015

(54) PLASMA-ASSISTED NANOFABRICATION OF TWO-DIMENSIONAL METAL CHALCOGENIDE LAYERS

(71) Applicants: Colin A. Wolden, Denver, CO (US); Rachel M. Morrish, Wheat Ridge, CO (US)

(72) Inventors: Colin A. Wolden, Denver, CO (US); Rachel M. Morrish, Wheat Ridge, CO (US)

(21) Appl. No.: 14/524,649

(22) Filed: Oct. 27, 2014

Related U.S. Application Data
(60) Provisional application No. 61/895,919, filed on Oct. 25, 2013.

(51) Int. Cl. C01G 49/12; G02B 1/00; B01J 27/047; C23C 14/00; C01G 41/00; C23C 16/515; C23C 16/30; C23C 14/08; H01B 1/10; B01J 27/043

(52) U.S. Cl. CPC C01G 49/12; H01B 1/10; G02B 1/002; B01J 27/047; B01J 27/043; C01G 41/00; C23C 16/515; C23C 16/305; C23C 14/08; C23C 14/0036
USPC 428/336; 252/519.4; 252/582; 502/216; 502/219; 502/222; 427/569; 428/432; 428/457; 428/698; 204/192.15

(57) ABSTRACT

The invention describes two methods for manufacturing metal dichalcogenide materials. The invention also includes a coated dichalcogenide substrate.

### CROSS-REFERENCE TO RELATED APPLICATIONS

This application claims priority under 35 U.S.C. §119(e) to U.S. Provisional Application Ser. No. 61/895,919, filed Oct. 25, 2013, which is incorporated by reference in its entirety.

### GOVERNMENT INTEREST

This invention was made with Government support under grant numbers CHE-1137400 and DMR-1207294 awarded by the National Science Foundation. The reference in its entirety.

### FIELD OF THE INVENTION

The invention relates to methods to produce metal chalcogenide layers. An aspect of the invention is a method to produce metal dichalcogenides using plasma-assisted conversion of metal oxides. Another aspect of the invention is a method to produce metal dichalcogenides by pulsed plasma-enhanced chemical vapor deposition. An aspect of the invention is a substrate coated with a metal chalcogenide.

### BACKGROUND

Two-dimensional (2D) metal dichalcogenides (WS₂, MoS₂, etc.) are molecularly thin sheets that have exhibited extraordinary optical properties, catalytic performance, and electronic structure. As semiconductors, 2D metal dichalcogenides complement more established 2D nanostructures such as graphene (conductor) and boron nitride (insulator). The potential to combine these materials as Van der Waals heterostructures in optoelectronics has opened a new paradigm in materials science worthy of extensive investigation.

2D nanosheets have typically been produced either by exfoliation from the bulk crystals or by direct synthesis. Synthesis of 2D dichalcogenides commonly employs exposure of transition metal precursors, typically oxides, to elemental chalcogen vapor at extremely high temperatures (more than 800° C.). These excessive temperatures not only limit the number of viable substrates, but are also cost prohibitive for large-scale production. The high temperature requirement reflects the limited reactivity of elemental chalcogens, which sublime as dimers and oligomers. The complexity of dealing with elemental chalcogens is non-trivial, and has hindered the large scale commercialization of CuInₓGa₁₋ₓSe_{y}S_{2-y} solar cells.

Due to the self-saturating surface half-reactions inherent to atomic layer deposition (ALD), it is an ideal technique for the synthesis of atomically-thin metal dichalcogenides. However limited reports to date indicate that available precursors do not display ideal self-limiting behaviors.

Thus, there is a need for a method of synthesizing 2D dichalcogenides at lower temperatures than current direct synthesis methods allow. There is additionally a need for a self-limiting method of producing substrates coated with metal chalcogenides that allows for precise control of layer thickness and stoichiometry.

### SUMMARY

The invention relates to a method to produce a metal chalcogen. The methods disclosed herein advantageously lower the required temperature to manufacture the metal chalcogen compared to methods without an elemental chalcogen. In addition, methods disclosed herein also advantageously allow metal chalcogen layers to be applied to substrates such that the thickness of the layers is controlled. The invention accelerates the fabrication and deployment of 2D metal dichalcogenides and related devices.

An aspect of the invention relates to plasma-assisted techniques for the nanofabrication of 2D metal dichalcogenides and related devices. The low temperature capability of these plasma-assisted techniques dramatically expands both material and process compatibility for scale-up and device integration. The composition and structure of these materials may be quantified with atom scale resolution. The fundamental understanding of intrinsic materials as well as the intrinsic materials' interactions within related 2D heterostructures may be guided and informed by density functional theory (DFT) and molecular dynamics (MD) simulations. In situ surface spectroscopy may be used to test theoretical predictions and provide insight into the processes used for deposition and modification.

An aspect of the invention relates to the use of plasma-assisted techniques to enhance chalcogen reactivity and overcome ALD's current limitations. By way of non-limiting example, the chemical potential of atomic sulfur can be about 3 eV greater than H₂S. This chemical potential can be utilized either in a direct two step H₂S plasma-assisted ALD process, or a three-step ALD process in which conventional ALD may be used to form the metal oxide, followed by sulfurization using an H₂S plasma. This oxide to sulfide conversion step may be thermodynamically favorable, and the invention demonstrates its advantages in the production of stoichiometric FeS₂. The invention extends this approach to other materials, by way of non-limiting example, the WO₃/WS₂ system, in which calibrated energy dispersive X-ray spectroscopy (EDAX) measurements confirm an about 2:1 stoichiometric sulfur to tungsten ratio.

An aspect of the invention relates to pulsed plasma enhanced chemical vapor deposition (PECVD). This technique may be used as an alternative to ALD for self-limiting growth of metal oxides. This technique may be used to achieve self-limiting growth of a metal dichalcogenide material, by way of non-limiting example, pyrite (FeS₂) with about sub-0.1 nm control by using H₂S and iron carbonyls. In embodiments of the invention, the iron carbonyls can be replaced with other materials, by way of non-limiting example, tungsten carbonyls to achieve self-limiting growth of WS₂ with similar levels of control (about 0.01 nm/pulse to about 0.1 nm/pulse). Detailed spatial analysis may be accomplished through simultaneous two-dimensional photoluminescence and Raman mapping capabilities. The invention can be directly extended to, by way of non-limiting example, MoS₂ using analogous precursors.

### BRIEF DESCRIPTION OF THE DRAWINGS

FIG. 1 illustrates the evolution of sulfur incorporation as a function of plasma exposure time at about 400° C.;

FIGS. 2A, 2B, and 2 C illustrate progressive field emission scanning electron microscopy (FESEM) images over three time periods for three samples;

FIGS. 3A and 3B illustrate magnified images (100,000×) of the films displayed in FIGS. 2A and 2C, respectively;

FIG. 4 illustrates samples after an about 5 minute exposure to the H₂S plasma at about 400° C.;

FIG. 5 illustrates degree versus intensity graphs for samples;

FIG. 6A illustrates spectra for the iron 2p and sulfur 2p regions;

FIG. 6B illustrates a high-resolution spectra of the sulfur 2p region verify conversion to FeS₂;

FIG. 7 illustrates the reflection corrected absorption coefficient (a) as hematite is converted to pyrite over time;

FIG. 8 illustrates a direct band gap Tauc plot for Fe₂O₃ (0 min) and FeS₂ (180 min) films;

FIGS. 9A and 9B illustrates Tauc analysis of samples;

FIG. 10A illustrates electrical characterization of fully sulfurized films;

FIG. 10B illustrates current-voltage characteristics of pyrite produced by about 90 minutes of plasma exposure are plotted;

FIG. 11 illustrates sulfur incorporation into an about 75 nm sputtered WO₃ film for an increasing plasma reaction time at about 500° C.;

FIG. 12 illustrates an Arrhenius plot of the plasma sulfurization process over a temperature range of about 350° C. to about 500° C.;

FIG. 13 illustrates temperature versus atomic ratio for samples at several thicknesses;

FIG. 14A illustrates a sample with an about 75 nm layer converted from oxide to sulfide at about 500° C. over time monitored with optical absorption spectroscopy;

FIG. 14B illustrates a plot of absorption at about 470 nm versus WS₂ film thickness;

FIG. 14C illustrates an estimation of the WS₂ thickness of a sample as a function of time;

FIG. 15 illustrates a Tauc analysis of a sample;

FIG. 16 illustrates a WS₂ sample;

FIG. 17 illustrates absorbance for samples with varying thicknesses;

FIG. 18 illustrates spectra collected from an about 75 nm WO₃ layer that is sulfurized at about 500° C. for increasing reaction times;

FIG. 19 illustrates an expanded view of the region surrounded by the dotted box in FIG. 18;

FIGS. 20A and 20B illustrate high-resolution spectra of the tungsten 4f and sulfur 2p regions of both WO₃ and fully sulfurized WS₂ surfaces

FIG. 20C illustrates survey scans of a WS₂ surface;

FIGS. 21A and 21B illustrate cross sectional FESEM images of the WO₃ and WS₂ films prepared on FTO substrates, respectively;

FIGS. 22A, 22B and 22C illustrate plan view FESEM images;

FIGS. 23A and 23B illustrate electrochemical characterization of an about 75 nm WS₂ sample on FTO;

FIG. 23C illustrates a preliminary electrocatalytic behavior of WS₂ on FTO compared against a bare FTO working electrode and a platinum foil;

FIG. 23D illustrates the stability of the prepared WS₂ electrode;

FIG. 24 illustrates a Tafel slope of about 150 mV/decade is calculated for the WS₂ electrode;

FIG. 25 illustrates optical spectra before and after HER stability testing;

FIG. 26 illustrates a plot of three different model fits for the conversion data as a function of time;

FIG. 27A illustrates images of the FTO glass substrates;

FIG. 27B illustrates the relationship of deposition rate with duty cycle;

FIG. 27C illustrates the stoichiometry as duty cycle is varied for films with a thickness of at least about 100 nm;

FIG. 28A illustrates the crystal phases present are evaluated by XRD and Raman spectroscopy with selected results;

FIG. 28B illustrates Raman spectra for several duty cycles;

FIG. 29A illustrates growth per cycle as a function of temperature for temperatures between about 180° C. and 380° C.;

FIG. 29B illustrates photographs of substrates after exposure to reactants at selected substrate temperatures;

FIGS. 30A, 30B, and 30C illustrates comparisons of representative FESEM images of the morphology obtained from the three deposition regimes: (i) thermal CVD at 380° C.; (ii) pulsed PECVD at T>300° C.; and (iii) pulsed PECVD at T<300° C.;

FIG. 30D illustrates differences between thermal CVD and pulsed PECVD films are also manifested in film composition;

FIG. 31A illustrates differences in composition between thermal CVD and pulsed PECVD films using XRD patterns;

FIG. 31B illustrates Raman spectra for pulsed PECVD at different temperatures and thermal CVD at 380° C.;

FIG. 32A illustrates the spectra collected by an optical emission spectrometer at different RF power;

FIG. 32B illustrates the relationship of deposition rate with plasma power;

FIGS. 33A and 33B illustrate both XRD and Raman characterization of films deposited as a function of plasma power;

FIGS. 34A, 34B, and 34C illustrate optical properties of a representative selection of films;

FIG. 35A illustrates samples characterized by Raman at different temperatures;

FIG. 35B illustrates the XRD patterns of the two films characterized in FIG. 35A;

FIG. 35C illustrates FESEM image of the film of FIG. 35A deposited at about 80° C.;

FIG. 35D illustrates the absorption coefficient of the film of FIG. 35A deposited at about 80° C. characterized by UV-Vis-NIR;

FIG. 36A illustrates Raman spectra of a thermal CVD, a pulsed-PECVD and a CW-PECVD films;

FIG. 36B illustrates the XRD patterns of films as a function of duty cycle;

FIG. 37A illustrates the transient behavior for two wavelengths for a plasma sample;

FIG. 37B illustrates the plasma intensity of argon under pulsed-PECVD at τ of about 0.67 (about 2 seconds on, about 1 second off) with and without W(CO)₆;

FIG. 38 illustrates a XRD pattern;

FIG. 39A illustrates XRD patters for films;

FIG. 39B illustrates a residue is observed on the substrate after deposition;

FIG. 39C illustrates TEM images of the powder of FIG. 39B;

FIG. 39D illustrates higher magnification TEM images of the powder of FIG. 39B;

FIG. 40A illustrates a XRD for series of films are deposited between about 20 nm and about 240 nm at τ to about 0.67, about 100 W, Tₛ to about 400° C., and about 400 mTorr;

FIG. 40B illustrates an image of the about 240 nm film of FIG. 40A;

FIG. 40C illustrates an image of the about 89 nm film; and

FIG. 40D illustrates polarization curves for the different thickness films of FIG. 40A.

### DETAILED DESCRIPTION

The invention relates to methods to produce metal chalcogenide layers. The invention includes two methods to produce metal dichalcogenides. One method produces the metal dichalcogenides using plasma-assisted conversion of metal oxides. Another method produces metal dichalcogenides by pulsed PECVD. The invention also relates to mestal chalcogenide layers.

### Plasma-Assisted Conversion of Metal Oxide

One aspect of the invention is a method to produce metal dichalcogenides using plasma-assisted conversion of metal oxide. The method includes depositing a metal oxide layer onto a substrate to create a coated substrate, exposing the coated substrate to a temperature between about 200° C. to about 600° C. to create a heated coated substrate, and exposing the heated coated substrate to an elemental chalcogenide to convert a metal oxide in the metal oxide layer to a metal chalcogenide.

Any suitable substrate may be used. By way of non-limiting example, the substrate may be glass, a wafer, a polymer, a metal, or other suitable material. The substrate may be any shape of any size. For example, the substrate may be a plate, rod, nano rod, sphere, cube, ovoid, pyramid, or other shape. In some embodiments, the substrate may be the metal oxide. The metal oxide may be selected from the group consisting of molybdenum oxide, iron oxide, tungsten oxide, titanium oxide, niobium oxide and combinations thereof or other similar materials. The elemental chalcogenide may be selected from the group consisting of sulfur, selenium, tellurium, polonium and combinations thereof. Any number of methods to deposit the metal oxide layer on the substrate may be used. In some embodiments, the metal oxide layer may be deposited to the substrate by vapor deposition, sputtering, atomic layer deposition, vacuum deposition, painting, dipping, combinations thereof, or other suitable methods. The metal oxide may be applied at thicknesses between about 1 nm and about 200 nm. Other thickness ranges may be used, such as a subrange of about 1 nm to about 2 nm. In some embodiments, the thickness of the metal oxide does not equate to the final thickness of the metal dichalcogenide layer. Thus, the thickness of the metal oxide layer may be applied such that a desired thickness of the metal chalcogenide layer may be achieved in the product. The metal oxide layer may be annealed prior to sulfurization. The annealing process may be carried out at vacuum, in air, or in the presence of an inert gas such as nitrogen, argon, helium, or the link. The annealing may be one or more of normalization, process annealing, full annealing, and short cycle annealing. The annealing may be carried out over a range of temperatures between about 300° C. and about 800° C. By way of non-limiting example, the annealing temperature may be about 500° C. The annealing may also be carried out for a time of between about 1 hr and about 5 hr. By way of non-limiting example, the annealing time may be about 1 hour. In some embodiments, the annealing temperature and time may be dependent upon the metal oxide.

After the metal oxide is deposited onto the substrate to create a coated substrate, the coated substrate is exposed to a temperature between about 200° C. to about 600° C. Any temperature within this range may be used. In some embodiments, the coated substrate may be exposed to a temperature of about 400° C., while in other embodiments, the coated substrate may be exposed to a temperature of about 500° C. The pressure during this heated exposure may be under a vacuum or at atmospheric pressure. In some embodiments, the exposure temperature of the coated substrate may be dependent upon the metal oxide applied to the substrate. By way of non-limiting example, if tungsten oxide is applied to the substrate as the metal oxide, a temperature of about 500° C. may be used, while if iron oxide is the metal oxide, a temperature of about 400° C. may be used, which may be based on a quick conversion while maintaining product purity.

Once the coated substrate has reached the temperature, it is exposed to elemental chalcogen. The pressure during this exposure may be at vacuum or may be atmospheric, for example between about 1 mTorr to atmospheric pressure. The exposure to elemental chalcogen may occur in an inert environment, such as in the presence of nitrogen, helium, argon or the like. Different methods may be used to introduce the elemental chalcogen. The chalcogen may be introduced in a plasma. By way of non-limiting example, the plasma type may be radio-frequency or inductively coupled. The coated substrate may be exposed to the chalcogen for between about 1 minute to about 60 minutes. Any exposure time within this range may be used. In some embodiments, the coated substrate may be exposed to the chalcogen for about 10 minutes, about 20 minutes, about 30 minutes, about 40 minutes and about 50 minutes. The metal oxide in the coated layer is converted to the metal chalcogenide after this exposure to the elemental chalcogen. After the exposure time has elapsed, the elemental chalcogen is no longer provided and the substrate coated with the metal dichalcogen may be returned to atmospheric conditions, if required.

The resulting metal dichalcogenide may be one or more of a molybdenum dichalcogenide, an iron dichalcogenide, a tungsten dichalcogenide, a titanium dichalcogenide, and a niobium dichalcogenide. Additionally, the resulting metal dichalcogenide may be one or more of a sulfide, a selenide, a telluride, and a polonide.

### Pulsed PECVD

Another aspect of the invention comprises a method to produce a metal chalcogenide coated substrate. The method includes mixing a vapor phase metal precursor with a chalcogen vapor precursor to form a vapor mixture and depositing the vapor mixture onto a substrate using pulsed plasma enhanced chemical vapor deposition to produce the metal chalcogenide coated substrate.

The substrate may be any suitable material, including but not limited to glass, metal, wafers or the like. The substrate may be any shape of any size. For example, the substrate may be a plate, rod, nano rod, sphere, cube, ovoid, pyramid, or other shape. In some embodiments, the substrate may be the metal oxide. Prior to coating the substrate, the substrate may be cleaned using any suitable method. By way of example only, the substrate may be cleaned using a cleaning detergent (such as Alconox), followed by a rinse with water, which may be tap water, deionized water, or distilled water. Following the water rinse, the substrate may be rinsed with an alcohol, including but not limited to, ethanol, isopropanol, methanol, or combinations thereof. The substrate may also be rinsed with an organic solution such as acetone, heptane, hexane, or the like, or combinations thereof. In some embodiments, the substrate may be etched. To etch the substrates, the substrate may be contacted with an acidic solution. By way of non-limiting example, the substrate may be submerged or rinsed with the acidic solution. The acidic solution may be hydrofluoric acid, hydrochloric acid, sulfuric acid or other suitable acid. The concentration of the acidic solution can be any suitable concentration.

The substrate may be heated during application of the mixture. In some embodiments, the substrate may be heated to between about 100° C. to about 500° C., or any temperature within this range. In some embodiments, the mixture is applied to the substrate at room temperature.

The ratio of the vapor phase metal precursor to the chalcogen vapor precursor may be between about 1: about 10 to about 1: about 100. The vapor phase metal precursor may be a metal carbonyl or a metal hexafluoride, through other metal precursors are contemplated. By way of non-limiting example, the vapor phase metal precursor may be an iron carbonyl, tungsten carbonyl, titanium carbonyl, niobium carbonyl, molybdenum carbonyl, iron hexafluoride, tungsten hexafluoride, titanium hexafluoride, niobium hexafluoride, molybdenum hexafluoride, and combinations thereof. The vapor phase metal precursor may be supplied in an inert environment, for example, in the presence of nitrogen, helium, argon or the like. The vapor phase metal precursor may be supplied by a bubbler. The temperature of the bubbler may be fixed at a particular temperature to achieve a desired constant flowrate of the vapor phase metal precursor. By way of non-limiting example, the constant flowrate of the vapor phase metal precursor may be between about 0.10 sccm and about 0.25 sccm.

The chalcogen vapor precursor may include a chalcogen, which may be selected from the group consisting of sulfur, selenium, tellurium, polonium and combinations thereof. By way of non-limiting example, in some embodiments, the chalcogen vapor precursor may be hydrogen sulfide, or hydrogen selenide. The chalcogen vapor phase precursor may be supplied by a bubbler. The temperature of the bubbler may be fixed at a particular temperature to achieve a desired constant flowrate of the chalcogen vapor phase precursor. By way of non-limiting example, the constant flowrate of the chalcogen vapor phase precursor may be between about 0.10 sccm and about 0.25 sccm

The chalcogen vapor precursor and the vapor phase metal precursor may be mixed with an inert gas before the chalcogen vapor precursor and the vapor phase metal precursor are mixed together. Alternatively, or in addition, the mixture may be in the presence of an inert gas. The inert gas may be at least one of nitrogen gas, argon, helium, neon, argon, krypton, xenon, or radon. The ratio of the chalcogen vapor precursor to inert gas may be between about 1:100 to about 1:10. The ratio of the vapor phase metal precursor to inert gas may be between about 1:100 to about 1:10.

The pulsed plasma enhanced chemical vapor deposition may be pulsed at a frequency between about 0.1 Hz to about 10 Hz. Any suitable frequency within this range may be used. The mixture may be delivered through a showerhead where the diameter of the showerhead is between about 5 cm and about 20 cm. In some embodiments, the showerhead may also serve as the powered electrode. Each pulse may apply a layer of the mixture at a thickness of between about 0.01 nm and about 0.5 nm. Any suitable thickness within this range may be used, and the total thickness of the layer need not be constant over the substrate. The pulse may be applied until the desired thickness of the material layer is achieved. The mixture may be applied at any temperature between about 100° C. to about 500° C., in some embodiments, between about 200° C. to about 400° C. The pressure during the pulsed plasma enhanced vapor disposition may be atmospheric, a partial vacuum or a full vacuum. In some embodiments the pressure may be between about 50 Pa to about 100 Pa.

The duty cycle during deposition may be between about 0.10 to about 1.0, or any value or subrange within this range. In some embodiments, the duty cycle may be about 0.5. The plasma power during deposition may be between about 10W to about 120 W, or any value or subrange within this range. In some embodiments, the plasma power may be about 100 W.

The resulting metal dichalcogenide may be one or more of a molybdenum dichalcogenide, an iron dichalcogenide, a tungsten dichalcogenide, a titanium dichalcogenide, and a niobium dichalcogenide. Additionally, the resulting metal dichalcogenide may be one or more of a sulfide, a selenide, a telluride, and a polonide.

### Metal Chalcogenide Coated Substrate

A further aspect of the invention is a metal chalcogenide coated substrate. The metal chalcogenide coated substrate includes a substrate and a film coating, which includes a metal dichalcogenide. The film coating has high stoichiometric purity, with a chalcogen atom to metal atom ratio of between about 1.9:1 and about 2.0:1.

In some embodiments, the metal chalcogenide may be one or more of a molybdenum dichalcogenide, an iron dichalcogenide, a tungsten dichalcogenide, a titanium dichalcogenide, and a niobium dichalcogenide. The metal chalcogenide may also be one or more of a disulfide, a diselenide, a ditelluride, and a dipolonide. By way of non-limiting example, the metal chalcogenide may be iron disulfide or tungsten disulfide.

In some embodiments, the film coating may have a thickness of between about 1 nm and about 200 nm. Any suitable thickness within this range may be used. By way of non-limiting example, the film coating may have a thickness of between about 1 nm and about 2 nm.

The substrate may be glass, metal, a wafer or other substrate to be coated. The substrate may be any shape of any size. For example, the substrate may be a plate, rod, nano rod, sphere, cube, ovoid, pyramid, or other shape. In some embodiments, the substrate may be the metal oxide.

Accordingly, the invention has been described with some degree of particularity directed to the exemplary embodiments of the invention. It should be appreciated though that modifications or changes may be made to the exemplary embodiments of the invention without departing from the inventive concepts contained herein.

### EXAMPLES

### Example 1

### Plasma-Assisted Conversion of Iron Oxide to Iron Sulfide by Hydrogen Sulfide

### Forming the Samples

Samples made using plasma assisted conversion are used to produce a substrate with an iron sulfide coating. The metal oxide is iron oxide (Fe₂O₃), the elemental chalcogenide is sulfur (S), and the metal chalcogenide is iron sulfide (FeS₂). The plasma-assisted sulfurization of Fe₂O₃ to FeS₂ is described by the stoichiometric Equation 1:

$${Fe}_{2} {O}_{3} + 4 {H}_{2} S {\to }^{plasma} 2 {FeS}_{2} + 3 {H}_{2} O + {H}_{2} \qquad ( 1 )$$

Fe₂O₃ nanorods grown on SnO₂:F-coated glass (fluorine doped tin oxide, FTO) by scalable chemical bath deposition are used as the starting material. Nanorods about 150 nm long are grown from an aqueous bath of FeCl₃ and NaNO₃. The as-deposited FeOOH nanowires are calcined in air at about 550° C. for about 20 min to produce a hematite phase. Samples are then placed on a resistively heated stage just downstream of an inductively coupled plasma (ICP) source used to activate an about 10% H₂5:90% argon mixture at about 5.8×10⁻⁵ atm. A rf power of about 80 W is applied, which is sufficient to dissociate nearly all the H₂5 feed.

### Testing of the Samples

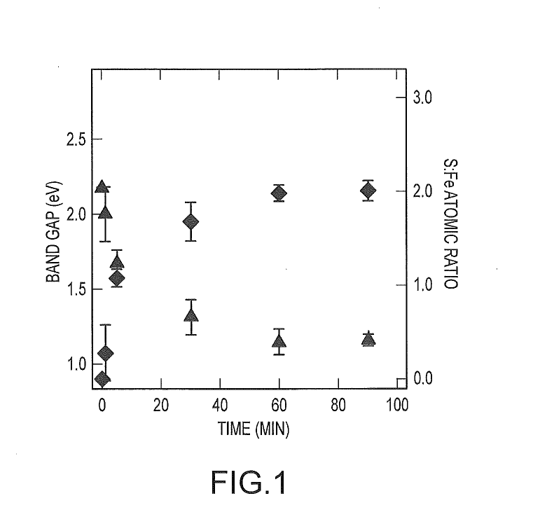

FIG. 1 illustrates the evolution of sulfur incorporation as a function of plasma exposure time at about 400° C. The sulfur to iron atomic ratio is measured using EDAX calibrated with a FeS₂ standard, as standardless quantification overestimates sulfur composition. An accelerating voltage of about 5 keV is adequate to survey the entire nanorod layer since the spectra include a significant tin signal from the underlying substrate. Error bars represent about 95% confidence intervals for three replicate samples. Within a given film, composition is typically uniform to ±3 atom %. Sulfur incorporation is observed after about 1 minute of H₂S plasma exposure and increased until saturating with a sulfur to iron atomic ratio of about 2.0±0.02 at about 60 minutes. The agreement with the expected FeS₂ stoichiometry supports a direct solid-state transformation of Fe₂O₃ to FeS₂, as clusters of residual Fe₁₋ₓS contaminates would depress the apparent sulfur content. Notably, this complete conversion is achieved using a chalcogen feed pressure 4 orders of magnitude lower than typical requirements for thermal sulfur vapor exposure (about 50 mTorr). Extended sulfurization times up to about 8 hours produce no further increase in the sulfur to iron atomic ratio, indicating an absence of elemental sulfur buildup. Deleterious sulfur condensation was not observed and may be avoided due to the low chalcogen feed pressure in combination with the presence of atomic hydrogen released from H₂S, which could scavenge sulfur contaminants.

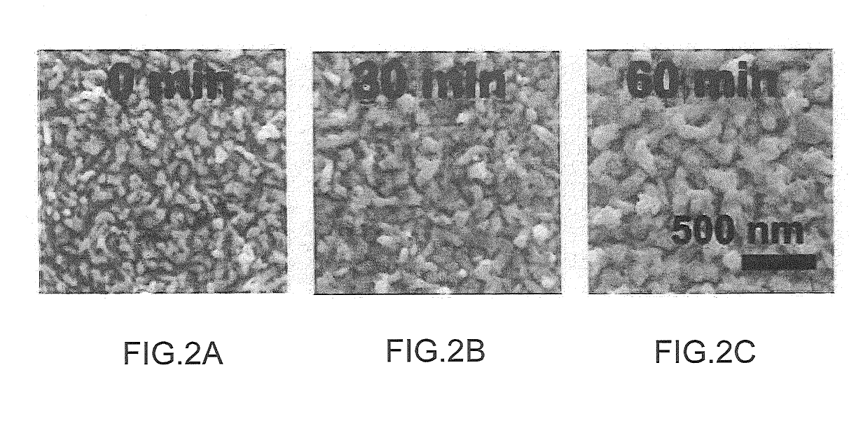

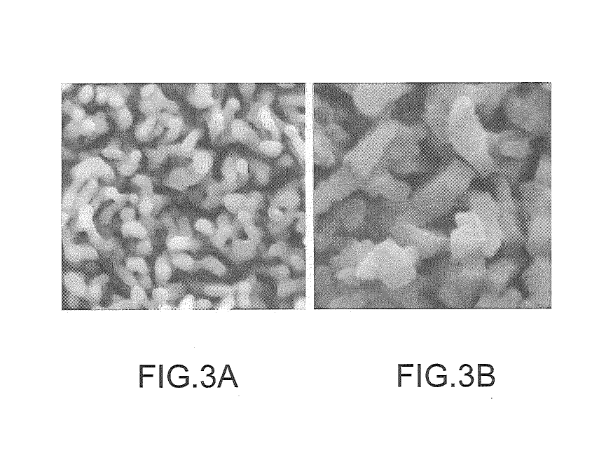

FIGS. 2A, 2B, and 2C illustrate progressive field emission scanning electron microscopy (FESEM) images over three time periods for three samples confirming that the surface of the film retains a nanostructured architecture throughout the conversion, though the characteristic feature size approximately doubles from about 50 to about 100 nm. FIG. 2A is a FESEM at 0 minutes. FIG. 2B is a FESEM at 30 minutes, while FIG. 2C is a FESEM at 60 minutes. Magnified images (100,000×) of the films displayed in FIGS. 2A and 2C are illustrated in FIGS. 3A and 3B, respectively. Surfaces of samples exposed for more than about 1 hour do not illustrate further changes, consistent with the composition measurements. The stable morphology suggests that the increase in feature size can be attributed to chemical effects of replacing, on average, about 1.5 oxygen atoms with about 2 sulfur atoms according to Equation 1. Nanorod growth could also stem from localized heating due to atomic hydrogen recombination, but such ripening would increase with time, and this is not observed.

As sulfur is incorporated into the nanorod film, the direct optical band gap determined from Tauc analysis, systematically decreases from about 2.2 eV (hematite) to about 1.2 eV (pyrite), as illustrated in FIG. 1. Indirect transitions are consistently measured to be between about 0.95 eV and about 1.0 eV for fully converted films.

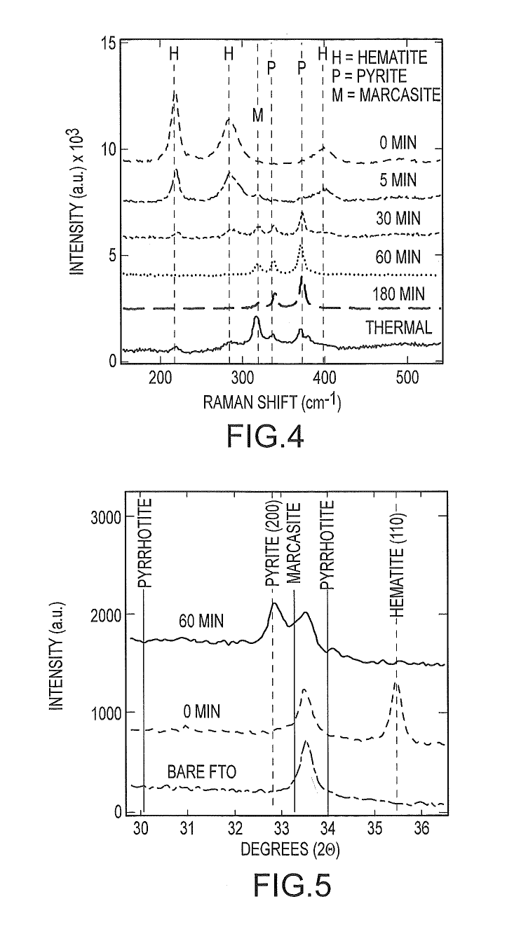

The chemical transformation from Fe₂O₃ into FeS₂ is tracked over time using Raman spectroscopy illustrated in FIG. 4. Raman is considerably more sensitive than X-ray diffraction (XRD) for distinguishing the pyrite and marcasite phases of FeS₂. Samples are analyzed with an about 532 nm diode laser configured to provide a resolution of less than about 1 cm⁻¹ over the region of about 150 cm⁻¹ to about 550 cm⁻¹. The samples were annealed in air at about 550° C. for about 20 min. The annealed Fe₂O₃ nanorods exhibit A_{g} bands at about 218 cm⁻¹ and E_{g} bands (energy gap) centered at about 284 cm⁻¹ and about 399 cm⁻¹, consistent with hematite analyzed at laser intensities greater than about 3 mW, where reversible localized heating causes both broadening and a slight red shift in peak positions.

As illustrated in FIG. 4, after an about 5 minute exposure to the H₂S plasma at about 400° C., new peaks at about 319 cm⁻¹, about 336 cm⁻¹, and about 373 cm⁻¹ are observed. The bands at about 336 cm⁻¹ and about 373 cm⁻¹ match the E_{g} and A_{g} modes of pyrite (P), respectively. As sulfurization progresses, the intensity of the hematite (H) signals decreases while the pyrite signals grow. After about 60 minutes the hematite phase is no longer observed. This reduction of the hematite signal agrees well with the EDAX data of FIG. 1, which illustrated a sulfur to iron stoichiometry of about 2:1 following an about 60 minute reaction. Raman penetration depth, which can be approximated by the inverse of the absorption coefficient (α⁻¹) most certainly decreased as sulfur was incorporated. In the most absorbing films, the inverse of the absorption coefficient corresponds to surveying the top about 80 nm of the about 150 nm thick nanorod layer.

The peak at about 319 cm⁻¹ in FIG. 4 is indicative of an A_{g} mode of marcasite (M), the orthorhombic polymorph of FeS₂. Although tin disulfide (SnS₂), an expected product of the sulfurized FTO substrate, has a strong A_{g} mode in this region as well (about 312 cm⁻¹), FeS₂ films prepared on bare glass exhibit an about 319 cm⁻¹ peak, confirming its assignment to marcasite. A second A_{g} mode of marcasite at about 382 cm⁻¹ appears as a shoulder on the dominant pyrite peak at about 373 cm⁻¹. Marcasite has an Eg of about 0.34 eV and is considered to be a contaminant within pyrite. Extended reaction times reduce the fraction of marcasite within the films, but cannot completely eliminate it to the detection limit of Raman. Raman spectroscopy appears to be markedly sensitive to marcasite impurities, as XRD analysis of the films indicates phase-pure pyrite, as illustrated in FIG. 5.

To assess the importance of applying a high sulfur activity plasma for conversion, a control sample is exposed to the same partial pressure of H₂S at about 400° C. for about 4 hours (FIG. 4, thermal). In addition to the significant portion of hematite still remaining within the film (S:Fe=1.20), the intensity of the marcasite peaks eclipses those of pyrite. Others have found gas-phase sulfurization of Fe₂O₃ with H₂S to be slow. In fact, Fe₂O₃ has been studied as a selective catalyst for gas-phase H₂S oxidation, implying its resistance to low-activity sulfurization. Greater sulfur pressures seem to favor formation of pyrite over marcasite, which could explain the improved phase purity obtained with plasma-activated H₂S.

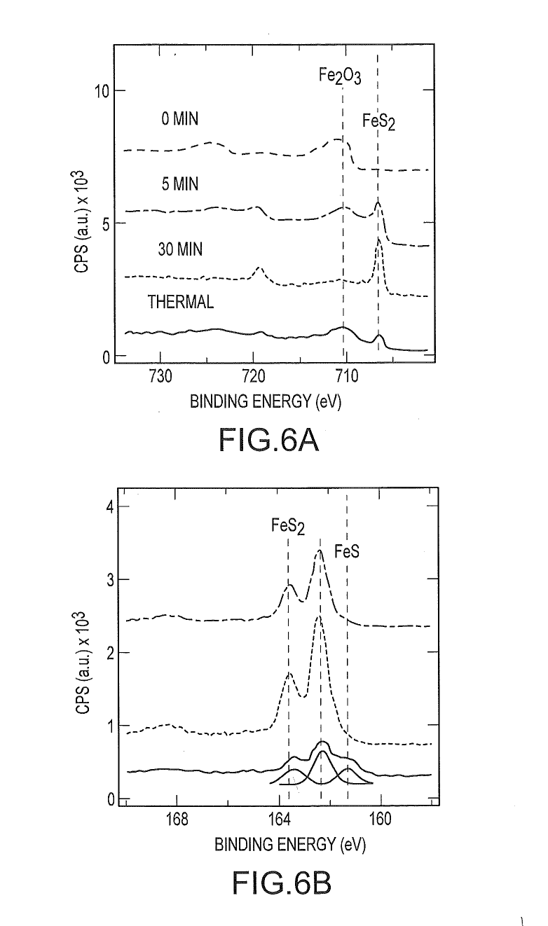

The surface chemistry of the sulfurized films is evaluated with an X-ray photoelectron spectrometer (XPS), as illustrated in FIG. 6. Argon sputter cleans are not used because sulfur is more readily etched than iron, complicating surface analysis. High-resolution spectra are collected at about 40 eV pass energy and aligned on the basis of adventitious carbon is at about 284.6 eV. Peaks are fit with a Shirley background and Voigt line shapes. FIG. 6(a) illustrates spectra for the iron 2p and sulfur 2p regions. The starting hematite film exhibits a primary 2p_{3/2} peak position of about 710.3 eV, corresponding to fully oxidized Fe³⁺ with the associated satellite peaks. After about 5 minutes of H₂5 plasma exposure, a peak at about 706.5 eV appears, matching Fe²⁺ in pyrite. By about 30 minutes, all evidence of superficial Fe₂O₃ has disappeared, replaced by FeS₂. A thermal sample was ran as a control. FIG. 6(b) illustrates a high-resolution spectra of the sulfur 2p region verify conversion to FeS₂, exhibiting only the expected spin-orbit-coupled 2p_{1/2} and 2p_{3/2} peaks at about 163.6 eV and about 162.4 eV, respectively (Δ=about 1.2 eV). Elemental sulfur (2p_{3/2}=164.0 eV) is not detected in any of the H₂S-exposed films. Sulfur to iron peak area ratios of completely converted FeS₂ surfaces range from about 0.62:1 to about 0.64:1, consistent with pyrite exposed to air. The subtle broad peak at about 169.5 eV to about 167.5 eV can be attributed to ferric sulfates.

While the thermally sulfurized sample does undergo partial conversion to FeS₂, it also contains a high fraction of FeS, illustrated in FIG. 6(b) by the additional sulfur peak at about 161.3 eV. When reacting with gas-phase H₂S, Fe₂O₃ converts to FeS₂ by exchange of O²⁻ for S²⁻. Even at elevated temperatures, equilibrium decomposition of gas-phase H₂S is less than about 10%, of which only a small fraction is the activated sulfur ion. Without sufficient sulfur activity, thermal H₂S sulfurization proceeds through the intermediate Fe₁₋ₓS phase en route to FeS₂. Conversely, application of a plasma results in more than 80% H₂S decomposition and is clearly able to support a direct solid-state transformation. The XRD data illustrated in FIG. 5 show no evidence of crystalline sulfur-deficient phases within the bulk of plasma-sulfurized films.

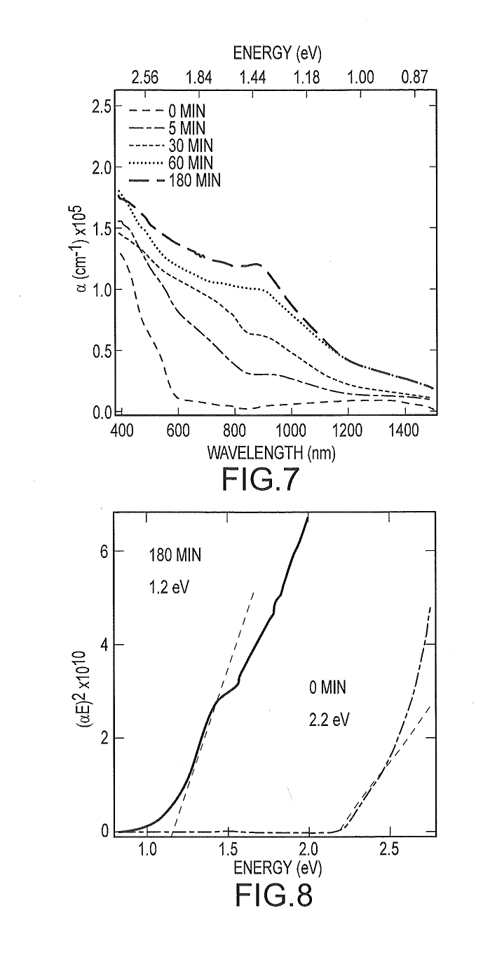

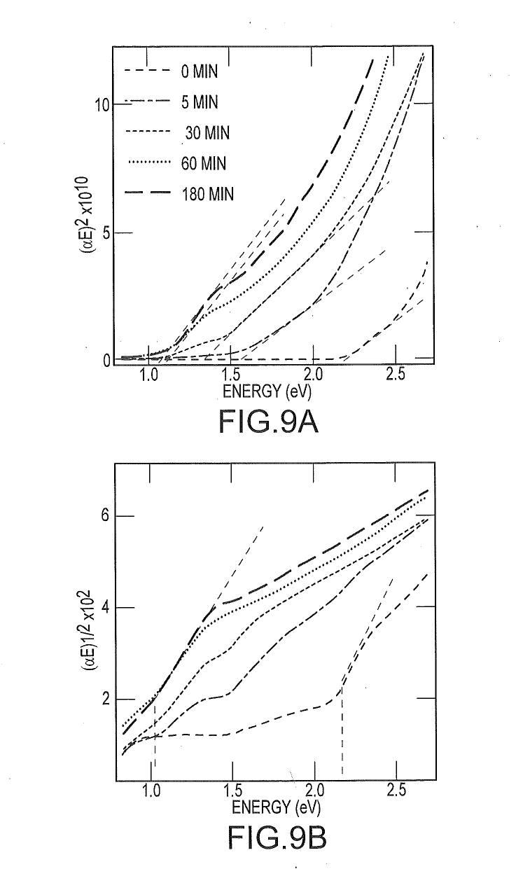

Pyrite's promise as a solar material is largely due to its favorable optical properties. FIG. 7 illustrates the reflection corrected absorption coefficient (a) as hematite is converted to pyrite over time. FIG. 8 illustrates a direct band gap Tauc plot for Fe₂O₃ (0 min) and FeS₂ (180 min) films. Fully converted FeS₂ layers exhibit a typical shape with α>10⁵ cm⁻¹ in the visible range. The soft band edge of FeS₂ compared to Fe₂O₃ could indicate a presence of defect states, though secondary transitions cannot be identified form either direct or indirect Tauc analysis, as illustrated in FIGS. 9A and 9B. Sulfurization beyond about 60 minutes does not change the absorption onset or optical band gap but does show a slight increase in a below about 1000 nm. Absolute values of a routinely vary by ±about 10% for replicate samples. This variation can be attributed to fluctuations in film thickness and local roughness, which influence the measured reflectance.

The gradual shift of the absorption onset from just below about 600 nm to more than about 1200 nm is not unlike trends observed in reverse type-1 heterostructures where a shell of low band gap material is overlaid on a wider gap material. As shell thickness is increased, an outward shift of electrons and holes allows the band structure to be tuned. This behavior is different than with two non-interacting planar layers, where primary transitions would be observed for each band gap so long as a significant fraction of light reaches the lower film. These heterostructures may serve as a reasonable model for H₂5 plasma conversion of Fe₂O₃ to FeS₂. Because the surface reaction initiates on the top layer of material, directly transforming hematite to pyrite, incident light will travel through the narrower band gap FeS₂ first. As the reaction front progresses, the growing pyrite overlayer causes a systematic shift to higher wavelength absorption. All films containing oxygen exhibit a values lower than stoichiometric FeS₂, which along with XPS further supports the direct transformation of hematite to pyrite without formation of intermediate alloys during plasma sulfurization.

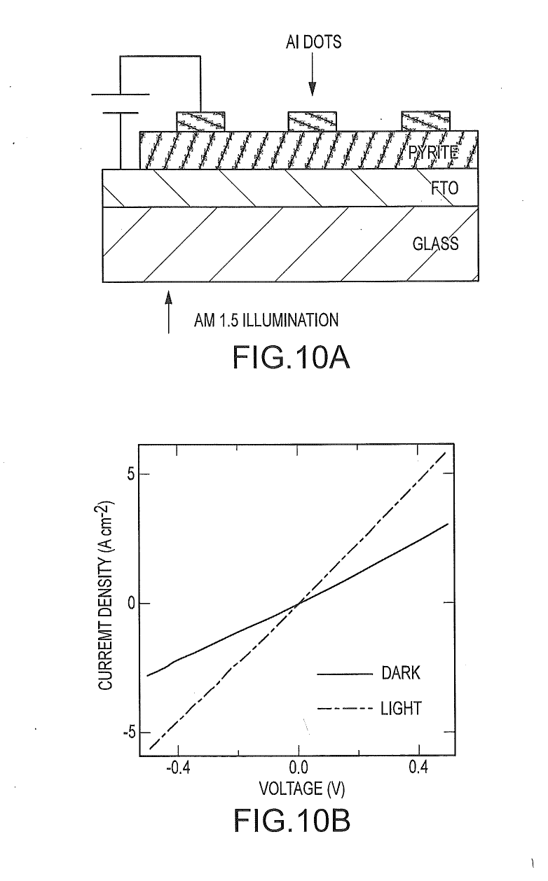

Preliminary electrical characterization of fully sulfurized films was tested by evaporating aluminum dots on the surface to measure pyrite photoconductivity, as illustrated in FIG. 10A. The current-voltage characteristics of pyrite produced by about 90 minutes of plasma exposure are plotted in FIG. 10B. The pyrite displays good ohmic behavior, and the dark conductivity is found to be about 1.1×10⁻⁴ S cm⁻¹, which falls between recent reports of about 1 S cm⁻¹ for highly pure, large-grain chemical vapor deposition (CVD) films and about 10⁻⁶ S cm⁻¹ obtained from dip-coated films assembled from pyrite nanocrystals. Compilation of majority carrier properties from a range of natural and synthetic forms of pyrite suggests maximum conductivities on the order of 1 S cm⁻¹. The conductivity values reported scale with grain size, implying that control of this parameter and passivation of grain boundaries are critical to the achievement of high-quality solar absorbers. Samples are also tested when lit from the back side using a calibrated AM 1.5 light source. Upon illumination, the conductivity more than doubles to about 2.3×10⁻⁴ S cm⁻¹. This photoresponse is comparable to reports for nanocrystalline pyrite when evaluated under the same applied voltage. Observation of measurable photoconductivity from a thin film suggests promise for application of nanostructured pyrite as a solar absorber.

### Example 2

### Plasma-Assisted Conversion of Tungsten Oxide to Tungsten Sulfide by Hydrogen Sulfide

### Forming the Samples

Samples made using plasma assisted conversion are used to produce a substrate with tungsten sulfide. The metal oxide is tungsten oxide (WO₃), the elemental chalcogenide is sulfur (S), and the metal chalcogenide is tungsten sulfide (WS₂).

Tungsten oxide thin films varying in thickness from about 30 nm to about 75 nm are deposited by reactive sputtering at ambient temperature onto FTO-coated glass. The thickness of the WO₃ layer is measured by spectroscopic ellipsometry on silicon witness samples that are included with each deposition. Samples are sulfurized in a custom-built ICP reactor consisting of an about 1 inch quartz tube with a copper coil connected to an about 13.56 MHz rf power supply and associated match network. A resistively heated stage position within the plasma sheath provides temperature control up to about 550±2° C. The sulfur plasma is generated at about 80 W from an about 10% H₂S/90% argon gas flow of about 40 sccm (about 450 mTorr) metered by a mass flow controller (MFC). All reported reaction times measure the lengths of plasma exposure only. Following reaction, the system is flushed with pure Ar. It typically takes less than 10 min to cool to less than 200° C. The system is cleaned with a pure H₂ plasma between runs. The as-deposited WO₃ thin films are amorphous, but it is presumed that these films are transformed into polycrystalline WO₃ when they are heated to about 500° C. prior to plasma exposure. To test the potential impact of crystallization, control samples are intentionally crystallized by being annealed in air at about 500° C. for about 1 hour prior to sulfurization. It is observed that the resulting WS₂ layers obtained from as-deposited WO₃ films and precrystallized WO₃ samples are indistinguishable. Polycrystalline WO₃ are used for all characterization comparisons.

### Testing of the Samples

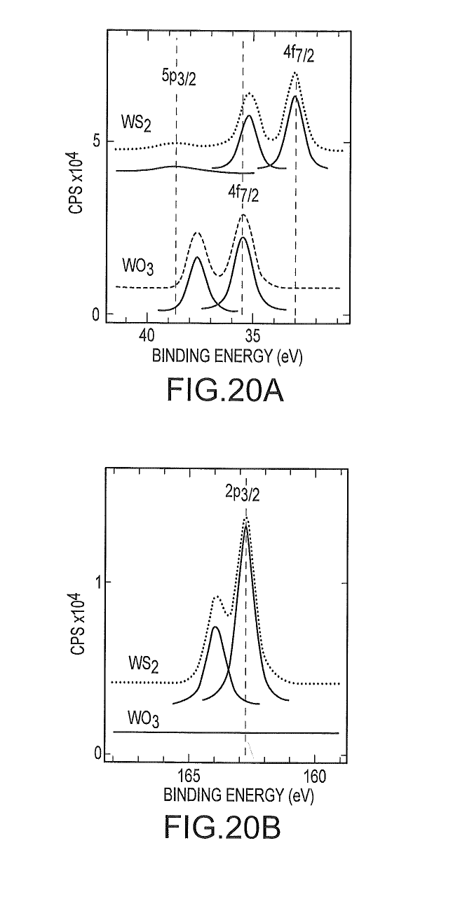

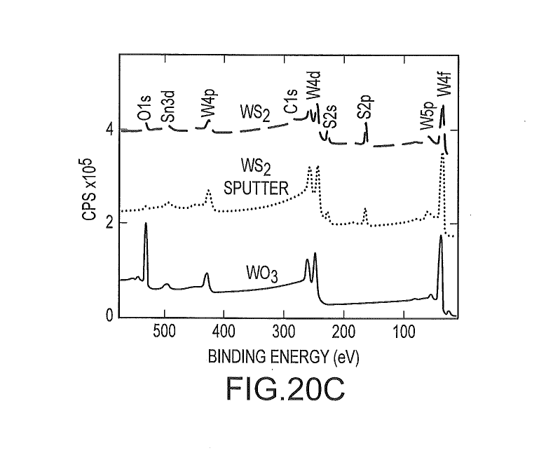

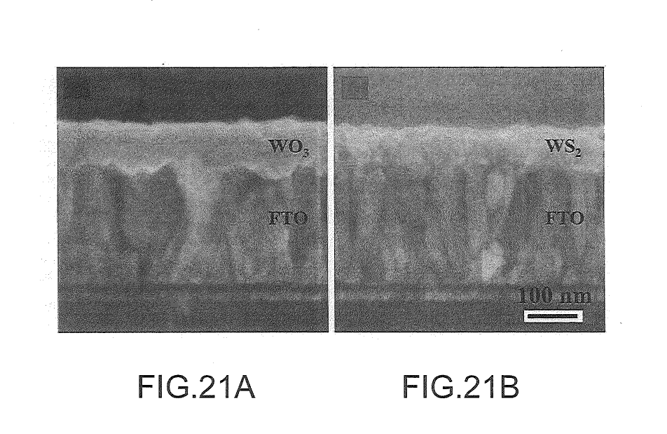

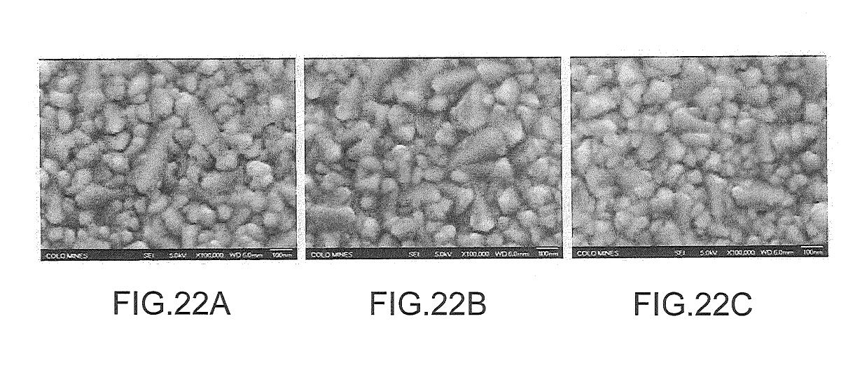

Samples are characterized by EDAX at an accelerating voltage of about 5 keV, which is sufficient to survey the entire layer. A WS₂ standard is used for composition calculations. A Cary 5G spectrophotometer equipped with an integrating sphere is used for optical characterization. Both transmission and reflection components are recorded to compute the absorption spectrum. Raman spectra are recorded with an about 532 nm diode laser at room temperature and are deconvoluted using Lorentzian line shapes. A Physical Electronics XPS with a monochromatic aluminum source is used for wide and high-resolution scans at pass energies of about 187.85 and about 23.5 eV, respectively. The spectra are aligned on the basis of adventitious carbon 1 s at about 284.6 eV and fit with a Shirley background and Voigt line shapes and discussed below with reference to FIGS. 20A through 20C. FESEM images are collected at about 5 keV and discussed below with references to FIGS. 21A through 22C.

All electrochemical measurements are conducted in an about 0.1 M H₂SO₄ electrolyte using a Gamry potentiostat with a standard three-electrode setup. The WS₂-coated FTO serves as the working electrode, platinum mesh as the counter electrode, and saturated Ag/AgCl as the reference electrode. Impedance data are collected at frequencies of 0.1 kHz to about 10 kHz. All potentials are corrected for pH and reported against the reversible hydrogen electrode (RHE).

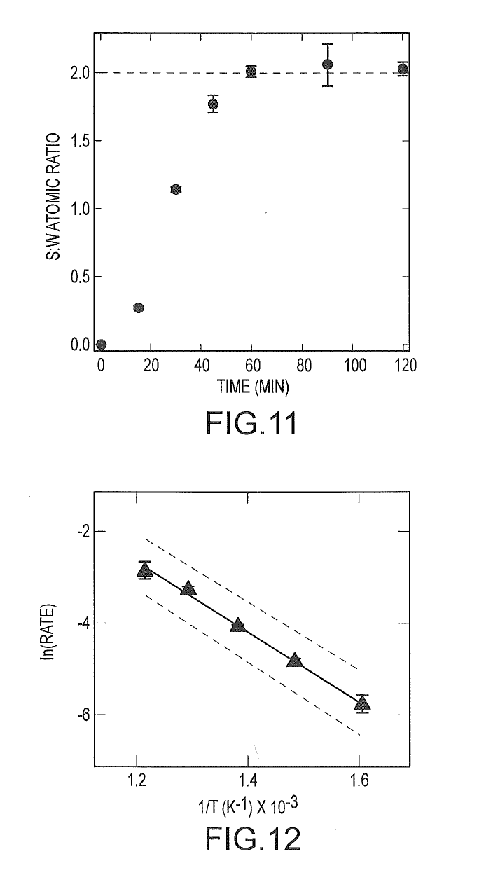

FIG. 11 illustrates sulfur incorporation into an about 75 nm sputtered WO₃ film for an increasing plasma reaction time at about 500° C. The sulfur to tungsten atomic ratio is measured using calibrated EDAX. The error bars represent about 95% confidence intervals from three areas surveyed at both central and edge locations on the about 4 cm² surface. For most samples, composition variation was less than about 3%, indicating a high degree of uniformity over the entire layer. Sulfur was observed after being exposed for about 15 minutes, and its level increased until an expected sulfur to tungsten ratio of about 2.0:1 was reached, which occurred at about 60 minutes; beyond that, no further change in stoichiometry occurred. The observed full conversion at about 500° C. allowed by plasma exposure is a significant reduction over the thermal reaction of H₂S with WO₃, which requires a minimum of about 400° C. to proceed but is more typically conducted at more than about 800° C.

The behavior of film conversion as a function of time, as illustrated in FIG. 11, reveals some insights into the reaction mechanism. Like many noncatalytic solid-fluid reactions, conversion of oxide to sulfide should occur in a series of steps: transport of reactive species to the surface, diffusion to the WS₂—WO₃ interface, chemical reaction, and finally transport of products back into the bulk. The slowest step or steps determine the apparent rate behavior for the process. If conversion is controlled by reaction, the rate will be proportional to the concentration of unreacted sites and to a first approximation will yield a linear relationship between conversion and time (S:W ∝ time). If the process is limited by diffusion, application of Fick's law predicts a square root dependence (S:W ∝ √time). Frequently, a combination of reaction controlling steps is observed, and a Deal-Grove model encompassing both mechanisms can be applied.

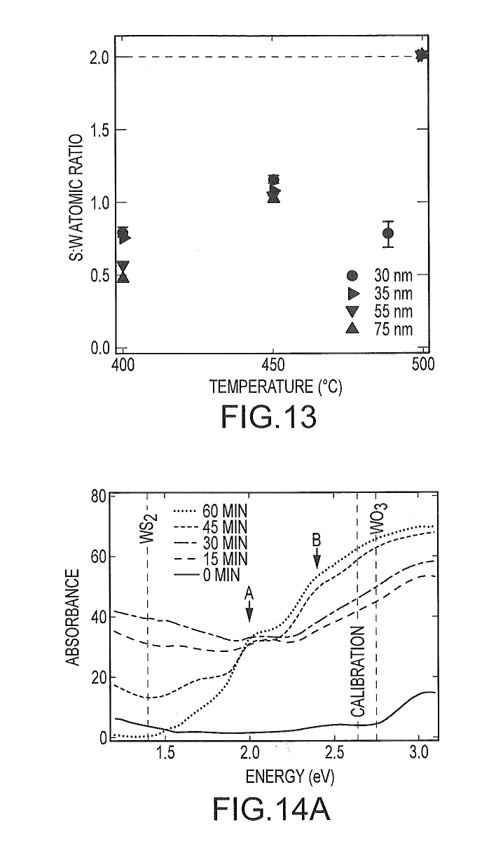

FIG. 12 illustrates an Arrhenius plot of the plasma sulfurization process over a temperature range of about 350° C. to about 500° C. An average reaction rate is computed by dividing the sulfur to tungsten ratio by the plasma exposure time in minutes. Because the atomic ratio saturates at a value of about 2.0, only samples that have not been fully converted to WS₂ are used for the calculation. The error bars represent about 95% confidence intervals for three separate sampling areas, and the dashed lines show upper and lower 95% confidence limits for the linear fit. The apparent activation energy (E_{A}) for H₂S plasma sulfurization of WO₃ is estimated from the slope of a least squares fit of ln(rate) versus T⁻¹ and was found to be about 63.6±1.9 kJ/mol. In comparison, the thermal reaction of H₂S with WO₃ has more than double the energy barrier with a reported value of about 151 kJ/mol between about 385° C. and about 590° C. This substantial reduction is attributed to the presence of energetic radicals such as atomic sulfur and hydrogen, whose heats of formation are about 300 kJ/mol and about 218 kJ/mol greater than those of H₂S and H₂, respectively. Sulfurization of varying WO₃ film thicknesses ranging from about 30 nm to about 75 nm is also explored. Although thinner layers illustrate a higher relative rate of sulfur uptake at lower temperatures, in all cases for varying thickness, an about 500° C. sulfurization temperature is required to achieve full conversion to WS₂, as illustrated in FIG. 13. The observed thickness dependence suggests that the process is controlled to some degree by diffusion, which is consistent with the evolution of optical properties.

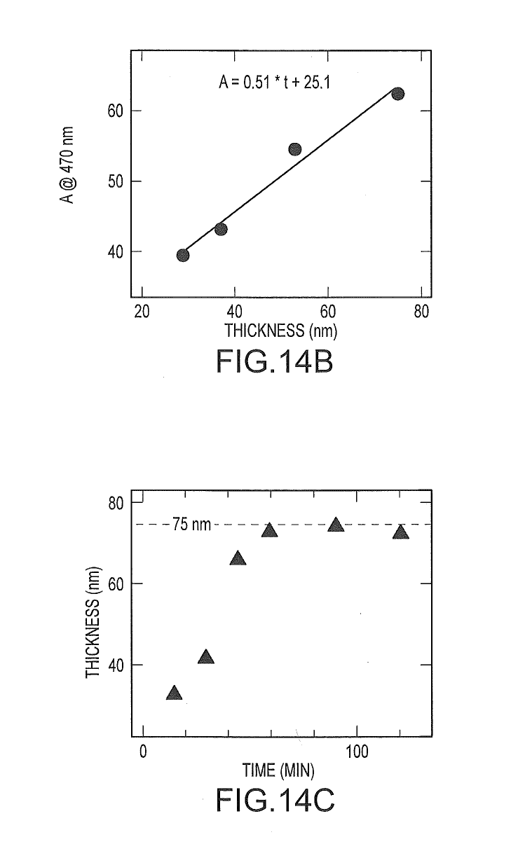

Transformation of the about 75 nm layer from oxide to sulfide at about 500° C. is also monitored over time with optical absorption spectroscopy, as illustrated in FIG. 14A. Bulk WO₃ and WS₂ are both indirect semiconductors with expected optical band gaps at about 2.9 eV and about 1.4 eV, respectively. FIG. 14B illustrates that a plot of absorption at about 470 nm versus WS₂ film thickness follows a linear Beer-Lambert law with thicker samples absorbing more light. The absorption at 470 nm appears to be linear and related to the slope by Equation 2:

Absorption_{470 nm}=0.51*thickness (nm)+25.1 (2)

The calibration is then applied to the spectra as a function of time to estimate the WS₂ thickness illustrated in FIG. 14C. The resulting trend of WS₂ film thickness as a function of time bears a marked resemblance to the measured sulfur to tungsten ratio illustrated in FIG. 11. This suggests that under partial sulfurization conditions the film is composed of a WO₃/WS₂ bilayer separated by a thin layer of reaction intermediates that give rise to low-energy (less than about 2 eV) absorption. The consistency between composition measurements and the optically derived WS₂ thickness implies that relative light absorption through the evolving layer could be utilized to monitor reaction progress in situ.

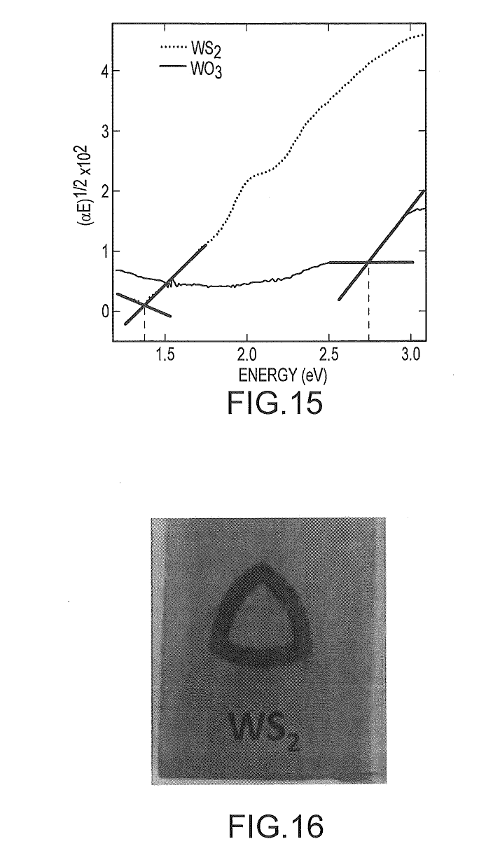

FIG. 15 illustrates a Tauc analysis confirming indirect transitions for the annealed WO₃ at about 2.75 eV and the fully sulfurized WS₂ layer at about 1.37 eV. The spectrum for WS₂ also contains a characteristic A-B excitonic pair with peak positions of about 2.0 and about 2.4 eV. These features arise from strong valence band spin-orbit splitting at the Brillouin zone K point and are observed in single crystals as well as polycrystalline films. This direct transition becomes predominate for atomically thin WS₂, and in the limit of a single layer, WS₂ converts to a direct gap semiconductor. Intermediate sulfurization times show a gradual evolution of the characteristic WS₂ excitonic features, and by about 45 minutes, an indirect transition at about 1.4 eV is detected. The broad absorption below about 2 eV has been observed for substoichiometric WS₂₋ₓ films and could result from an oxy-sulfide intermediate that may also convolute the underlying WO₃ signal. At about 2.5 eV, the absorption coefficient for the fully sulfurized layer is about 5×10⁴ cm⁻¹, which is comparable to other reported values for WS₂ thin films.

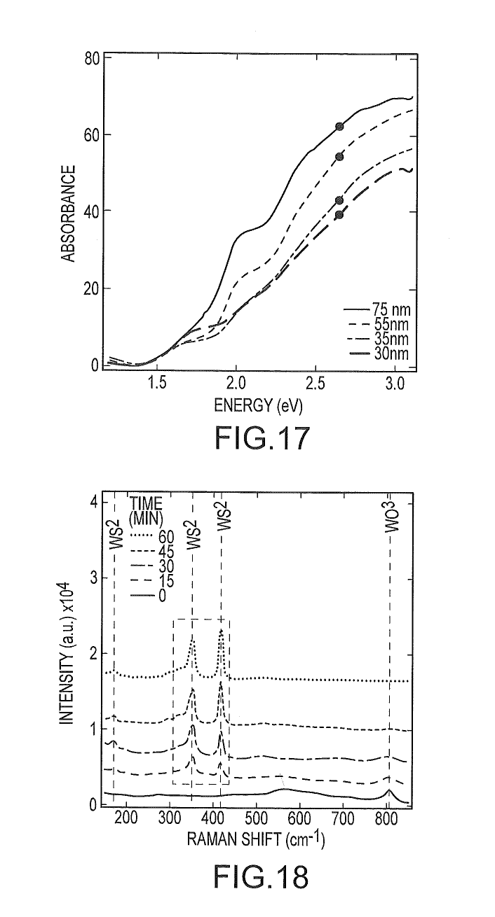

Visually, the WS₂ samples appear as a characteristic dark tan color, as illustrated in FIG. 16, with higher levels of saturation at longer reaction times as illustrated by the increasing absorption beyond the band gap in FIG. 17. To estimate the WS₂ layer thickness as the reaction progresses, a set of fully sulfurized samples of known height are used to generate a calibration of light absorption versus WS₂ thickness, as illustrated in FIG. 17. A wavelength of about 470 nm (about 2.64 eV) is chosen for the calibration because absorption by WO₃ is negligible in this region. The points on each line at about 2.7 eV correlate with the predicted absorbance from Equation 2.

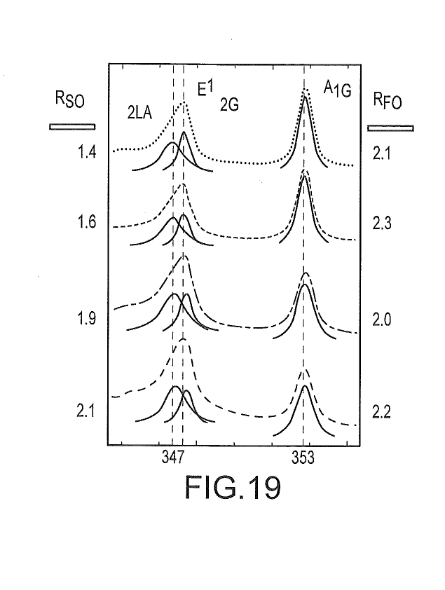

Formation of WS₂ over time is confirmed by Raman spectroscopy. FIG. 18 illustrates spectra collected from an about 75 nm WO₃ layer that is sulfurized at about 500° C. for increasing reaction times. FIG. 19 illustrates an expanded view of the region surrounded by the dotted box in FIG. 18, in which the 2(LA(M)) and E¹_{2G} shifts centered at about 347 cm⁻¹ and about 353 cm⁻¹, respectively, can be discerned along with the A_{1G} mode, a characteristic vibration/rotational mode of the molecule, at about 417 cm⁻¹. The magnified spectra are normalized to the A_{1G} intensity for the sake of clarity. As expected, the annealed WO₃ crystallizes in the stable monoclinic structure with a distinct O—W—O stretching band at about 806 cm⁻¹ illustrated in FIG. 18. Following sulfurization, characteristic first-order (FO) WS₂ modes appeared at about 171 (LA(M)) about 352 (E¹_{2G}), and about 417 cm⁻¹ (A_{1G}). At longer reaction times, the relative amount of WO₃ decreased and disappeared while the intensity of the WS₂ peaks increased. These spectra are consistent with the EDAX surveys that found that about 60 minutes at about 500° C. is required for full conversion of an about 75 nm layer, as illustrated in FIG. 19.

As the reaction proceeds and the WS₂ layer grows, the relative intensities of the two primary WS₂ bands change. Initially, the about 352 cm⁻¹ peak is higher than the about 417 cm⁻¹ peak, but after longer reaction times, the prominence reverses. Tungsten disulfide is known to exhibit second-order (SO) resonance modes with Raman excitation wavelengths near its band gap energies, and in this case, the about 532 nm (about 2.33 eV) laser light is just below the B exciton transition, resulting in an amplified SO 2(LA(M)) peak convoluted with the E¹_{2G} mode. While the area ratio of the FO peaks (R_{FO}=I_{A1G}/I_{E12G}) remains nearly constant at 2.15±0.15 during processing, the ratio of the resonant SO peak (R_{SO}=I_{2LA}/I_{E12G}) systematically decreases with reaction time, causing the apparent switch in primary peak intensity. A similar trend is observed for WS₂ nanotubes and fullerene-like particles where an increase in the length scale results in a decrease in 2(LA(M)) intensity. This is consistent with expansion of the WS₂ layer from about 30 nm at about 15 minutes to about 75 nm after complete sulfurization. The observed subtle narrowing of the A_{1G} peak at longer reaction times may be an additional indicator of the material's feature size. The SO:FO ratios used as a fingerprint for single-sheet material are based on a double resonant mode that apparently occurs exclusively at about 514 nm excitation whereas the features in this embodiment evolve from resonance processes that are present even in bulk systems.

The phase purity of the synthesized WS₂ layer is confirmed by XPS. FIGS. 20A and 20B illustrate high-resolution spectra of the tungsten 4f and sulfur 2p regions of both WO₃ and fully sulfurized WS₂ surfaces. The annealed tungsten oxide layer matches WO₃ (about 35.5 eV for 4f_{7/2}) and contains no sulfur. Sulfurization causes tungsten to shift to a lower binding energy (about 33.0 eV for 4f_{7/2}) as it is converted from a +6 valence state bound to oxygen to a +4 valence state bound to sulfur. The spectra are well fit with a single set of spin-orbit-coupled peaks indicating that the plasma processing converts all oxide to sulfide. As illustrated in FIG. 20B, sulfur exhibits a −2 valence state (about 162.7 eV for 2p_{3/2}) as well as the expected about 1.8 eV doublet separation and a 2p_{3/2}:2p_{1/2} area ratio of about 2.0, all of which verify a single WS₂ phase assignment in the prepared material. Survey scans of this WS₂ surface, as illustrated in FIG. 20C, illustrate primarily sulfur and tungsten with an atomic ratio of about 2:1 calculated by standard relative sensitivity factors. These spectra are recorded less than about 6 hours following sulfurization. Even with the relatively short atmospheric exposure, some adventitious oxygen and carbon were present. A relative lack of inelastic background scattering around the oxygen peak compared to bulk tungsten and sulfur indicates that the oxygen is superficial, and following an about 1 minute sputter, the overall oxygen content decreases to less than about 3 atom % in the film. High-resolution scans are not evaluated after sputtering because sulfur is more readily etched than tungsten and it is well-known that tungsten is reduced when it is bombarded with argon ions. WS₂ surveyed more than a day after conversion did contain oxide as has previously been observed after prolonged storage under ambient conditions. The survey scans also reveal the presence of approximately 2% tin that is detected in the annealed WO₃ and WS₂ films. The tin comes from the underlying FTO and diffuses into the tungsten layer during heating. Unlike adventitious oxygen and carbon, the relative tin concentration remains unchanged after the sputter clean. This behavior is observed in the preparation of Fe₂O₃ photoanodes on FTO substrates, and in that case, tin doping is linked to improved photoactivity.

Cross sectional FESEM images of the WO₃ and WS₂ films prepared on FTO substrates are illustrated in FIGS. 21A and 21B, respectively. Measured thickness values of the WO₃ and sulfurized WS₂ layers are about 81 nm±9 nm and 77 nm±5 nm, respectively. The WO₃ thickness is consistent with the about 75 nm value estimated from ellipsometry on the jointly deposited silicon wafer substrate. Although sulfurization may decrease the layer thickness slightly, within error, the height is nominally unchanged. This change in thickness is expected because the specific volume of the two materials differs by less than about 8%. Plan view FESEM images illustrate that both the sputtered WO₃ and subsequent plasma-processed WS₂ conform to the crystalline FTO, and in fact, the three surfaces cannot be discerned from one another, as illustrated in FIGS. 22A, 22B (WO₃), and 22C (WS₂). Close inspection of the FESEM image in FIG. 21B reveals approximately 50 nm crystalline grains in the WS₂ film, and XRD spectra of these thin layers contain peaks corresponding to the 2H structure.

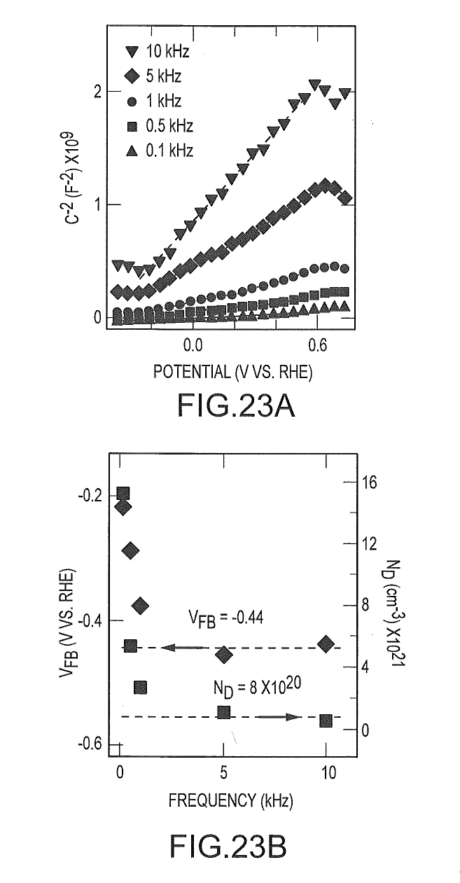

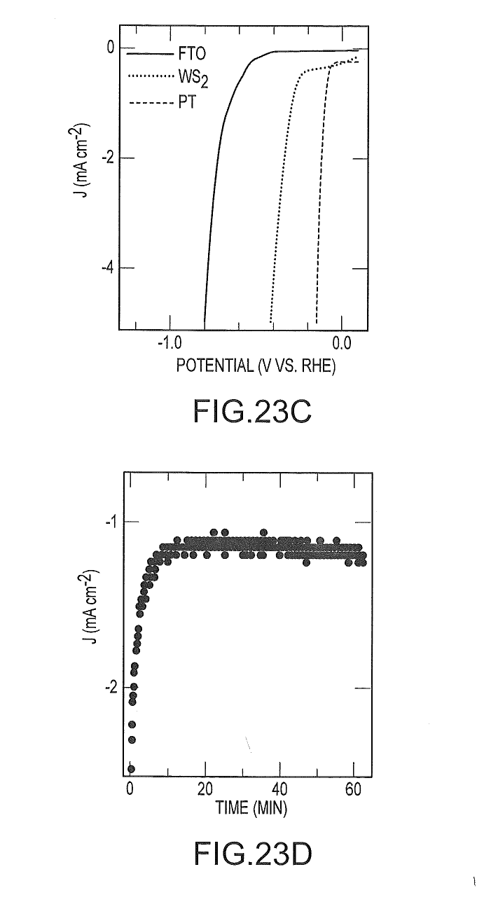

Electrochemical characterization of an about 75 nm WS₂ sample on FTO is illustrated in FIGS. 23A and 23B. FIG. 23A illustrates Mott-Schottky analysis of the impedance with an increasing frequency assuming a planar electrode surface. The plot of inverse squared capacitance (C⁻²) versus applied potential (V) exhibits a good linear response between −0.25 and 0.5 V versus the reversible hydrogen electrode, with the positive slope signifying n-type conductivity. Calculated values of the flat band potential, V_{FB}, and donor density, N_{D}, as a function of frequency are illustrated in FIG. 23B. A relative dielectric constant of 10 is assumed for WS₂. At low frequencies, V_{FB} and N_{D} vary substantially, likely because surface states contribute to the capacitance signal. At approximately 5 kHz, both values plateau and the average beyond this point yields the Equations 3 and 4.

V_{FB}=−0.044±0.05 V versus RHE (3)

N_{D}=8*10²⁰ cm⁻³ (4)

Preliminary electrocatalytic behavior of WS₂ on FTO is also tested and compared against a bare FTO working electrode and a platinum foil illustrated in FIG. 23C. The curve of current density, J (milliampers per square centimeter), versus applied potential illustrates that the onset for the hydrogen evolution reaction (HER) on WS₂ falls between FTO and platinum. The overpotential values, determined where the derivative of the J-V curve reaches about 0.02 mA cm⁻² V⁻¹, for platinum, WS₂ and FTO are about 85 mV, about 330 mV, and about 690 mV, respectively. While the measured overpotential is substantially lower than reported values for bulk WS₂, the prepared thin film does not exhibit the high catalytic activity of monolayer sheets. The stability of the prepared WS₂ electrode is illustrated in FIG. 23D. When held at an applied potential of about -0.36 V versus RHE, the current density remains substantially constant for more than about 1 hour passing a total charge of approximately 4.2 C cm⁻². The initial drop during the first about 5 minutes of the run is normal for all electrodes including platinum.

While pure single-crystalline WS₂ is an n-type semiconductor, polycrystalline films prepared by a variety of methods are frequently reported to show p-type behavior. Excess sulfur or other contaminates have been suggested as possible culprits, though for preparations relying on a nickel buffer layer to direct crystalline orientation, the nickel may infuse into the WS₂ lattice and act as an electron acceptor. In this embodiment, XPS analysis reveals the presence of tin doping that occurs during heating in contact with the underlying FTO. This tin could act as a substitutional electron donor or otherwise induce defects that favor n-type behavior in these WS₂ films. Thin films exhibiting n-type behavior have been associated with extreme sulfur deficiencies (WS_{1.6}), but given the corroborated stoichiometry of these films, this explanation is implausible. For n-type materials, a large negative V_{FB} like the measured value of about −0.44 V suggests a desirable low photocurrent onset potential for the oxygen evolution half-reaction during solar water splitting. The incorporation of tin may be responsible for the relatively high measured donor density of about 10²⁰ cm⁻³ that is typically less than 10¹⁸ cm⁻³ for p-type polycrystalline WS₂. Similar tin doping concentrations in TiO₂ nanotubes produces an increase in N_{D} of approximately 3 orders of magnitude.

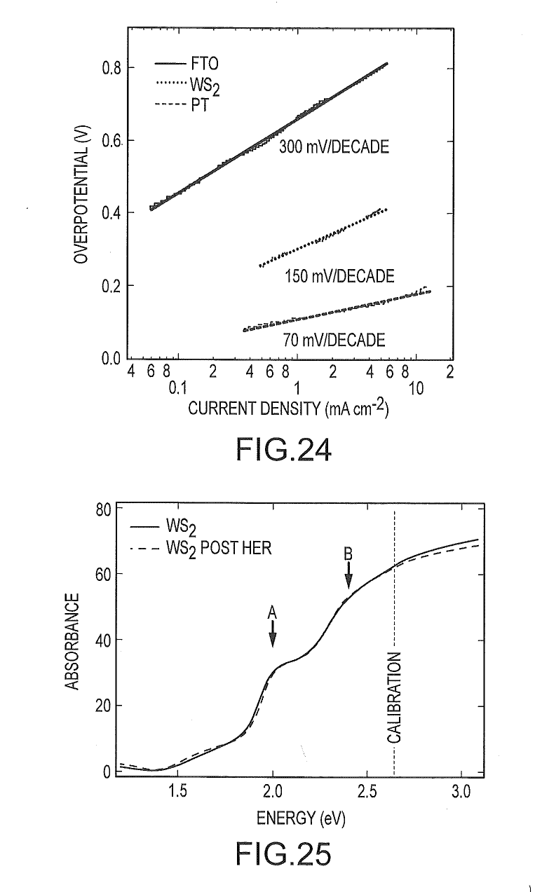

A Tafel slope of about 150 mV/decade is calculated for the WS₂ electrode, as illustrated in FIG. 24, though this value is likely overestimated because the data are not corrected for ohmic voltage losses. For comparison, the platinum Tafel slope is about 70 mV/decade whereas typical values are less than about 50 mV/decade. Both the WS₂ overpotential and Tafel slope closely match a report of hydrothermally prepared tungstenite sheets. The observed high Tafel slope for this material indicates that the primary discharge Volmer reaction is rate-limiting. Optical spectra before and after HER stability testing, as illustrated in FIG. 25, are nearly identical with absorption at the calibration point of about 470 nm corresponding to a film thickness change of less than about 1 nm. Optical spectra of a 75 nm WS2 sample (A in FIG. 25) as-prepared out of the plasma reactor and after exposure to 0.1 M H2SO4 with applied potential of -0.36 V vs RHE (B in FIG. 25).

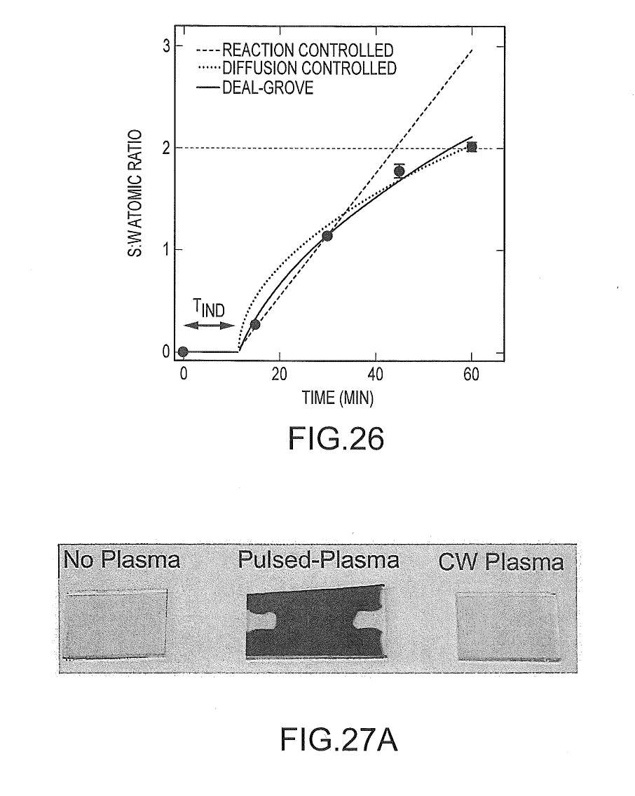

FIG. 26 illustrates a plot of three different model fits for the conversion data as a function of time: reaction-controlled, diffusion-controlled, and Deal-Grove. Application of these straightforward models is only possible when an induction period (t_{ind}) of about 10 minutes is included. This induction time is estimated as the x-intercept from a linear fit of the first two data points and could be associated with a removal of surface contamination that builds up between WO₃ deposition and plasma sulfurization. Although the reaction-controlled mechanism initially provides a good fit, it deviates from data at long reaction times. Conversely, the diffusion-controlled model is more appropriate in the final stages of conversion. While not wanting to be bound by theory, the process is governed by chemical reaction at first, and diffusion becomes more important as the WS₂ layer grows with a transition point occurring between about 30 and about 45 minutes (about 40 nm to about 65 nm product layer thickness). The combination of both reaction and diffusion steps in a Deal-Grove model achieves the best fit.

Because of its relevance to catalytic hydrotreating of crude oil, the thermal reaction of H₂S with WO₃ to form WS₂ has been studied well. The high W—O bond energy (about 670 kJ/mol) necessitates that the first step be reduction of W⁶⁺ to W⁵⁺. This is different from MoO₃/MoS₂ conversion where a direct sulfur for oxygen exchange takes place and is one reason why higher temperatures are typically required for sulfurization to form WS₂. In the plasma sulfurization process, this reduction could be readily achieved by atomic hydrogen that is formed from dissociation of the H₂S gas feed. The high reactivity of atomic hydrogen could facilitate tungsten reduction and explain how full conversion is achieved at a relatively low temperature of about 500° C. The measured apparent activation energy of about 64 kJ/mol reflects contributions from energy barriers for all controlling steps of the reaction. For the conventional thermal conversion process, the reported activation energy of about 150 kJ/mol was attributed to activated diffusion. Because both reaction and diffusion mechanisms influence the rate during plasma sulfurization, it may be that the high sulfur activity effectively catalyzes the reaction step and lowers the overall barrier.

### Example 3

### Pulsed PECVD with Iron Pentacarbonyl and Hydrogen Sulfide Precursors to Form Iron Sulfide

### Forming the Samples

The metal precursor is iron pentacarbonyl Fe(CO)₅ IPC, the chalcogen vapor precursor is hydrogen sulfide (H₂S), and the vapor mixture is iron sulfide (FeS₂). Pulsed PECVD is performed in a capacitatively coupled parallel plate reactor evacuated by a mechanical pump to a base pressure less than about 1 Pa. Reactants are premixed and delivered through an about 13.9 cm diameter showerhead, which also serves as the powered electrode. A matching network ensures that the reflected power is negligible. A mixture of about 10% H₂S in argon is controlled by a mass flow controller (MFC) at flowrates between about 40 sccm and about 120 sccm. Iron pentacarbonyl is stored in a bubbler at about 5° C. and about 66 kPa and argon controlled by an MFC is used as the carrier gas. A third MFC is used to add variable amounts of argon (20 sccm to about 110 sccm) to ensure a pressure of about 53 Pa. Substrates include both silicon wafers and FTO coated glass with a nominal size of about 3.5 cm×3.5 cm. FTO coated glass is sonicated in a solution of Alconox cleaning detergent for about 5 minutes and then rinsed consecutively with DI water, acetone, and methanol. Silicon substrates are dipped in an about 2% HF solution to remove native oxide. Substrates are attached to the center of the grounded electrode located about 5.7 cm above the showerhead. Substrates are heated with a resistance heater and the temperature is monitored with a thermocouple. An optical emission spectrometer (OES) is positioned outside the reactor to monitor the emission spectrum of the plasma through a site glass.

### Testing of the Samples

Preliminary experiments were performed to identify the critical variables and establish the parameter space. Table 1 summarizes the baseline values for these parameters and the approximate ranges explored.

TABLE 1

| Parameter | Baseline | Range |
|---|---|---|
| Plasma off time, t_{off} (s) | 1 | 0.5-5 |
| Plasma on time, tₒₙ (s) | 2 | 1-6 |
| Duty cycle (τ) | 0.67 | 0.17-0.86 |
| Substrate temperature (° C.) | 240 | 180-380 |
| RF power (W) | 50 | 15-100 |
| IPC flowrate (sccm) | 0.25 | Fixed |
| H₂S:IPC ratio | 36 | Fixed |
| Pressure (Pa) | 53 | Fixed |

The IPC bubbler conditions were fixed to deliver IPC at a constant flowrate of about 0.25 sccm. H₂S was supplied in excess to ensure full conversion to stoichiometric FeS₂. H₂S:IPC ratios in the range of about 16 to about 48 were explored and found to have a negligible impact on deposition rate, film composition, or optical properties. For the films described below the ratio was fixed at H₂S:IPC of 36. The sensitivity of the process to pressure was explored over a range of about 53 Pa to 93 Pa. This variable also had no impact on the deposition process, and the pressure was fixed at about 53 Pa. The variables found to most strongly impact deposition rate and quality were duty cycle (τ), substrate temperature (Tₛ), and plasma power.

Film thickness and deposition rate are quantified by imaging cross-sections of samples deposited on silicon with a JEOL JSM-7000F FESEM. An EDAX energy dispersive spectrometer (EDS) attached to the FESEM is used to determine film stoichiometry. EDS is measured using an about 5 kV accelerating voltage and calibrated based on a pyrite standard. However, for thin films (less than about 200 nm), this procedure yields sulfur to iron ratios much greater than 2:1, a problem that is exacerbated as the thickness is reduced. To correct for film thickness, EDAX measurements are quantified using the Pouchou and Pichoir model for stratified specimens. EDAX measurements are the most reproducible for film thicknesses of at least about 100 nm, and reports of composition are limited to these samples. XRD is measured with a Siemens D500 diffractometer with a Cu Kα (λ=0.154 nm) X-ray source. Raman spectra are collected with a WITec Alpha 300R Confocal Raman Microscope at an excitation wavelength of λ=532 nm and about 100× magnification. Optical properties are measured with a Cary 5G UV-Vis-NIR spectrophotometer equipped with an integrating sphere. Transmittance and reflectance are measured for the range 2 of about 1500 nm to 350 nm, and the contributions of the underlying FTO-coated glass are background subtracted.

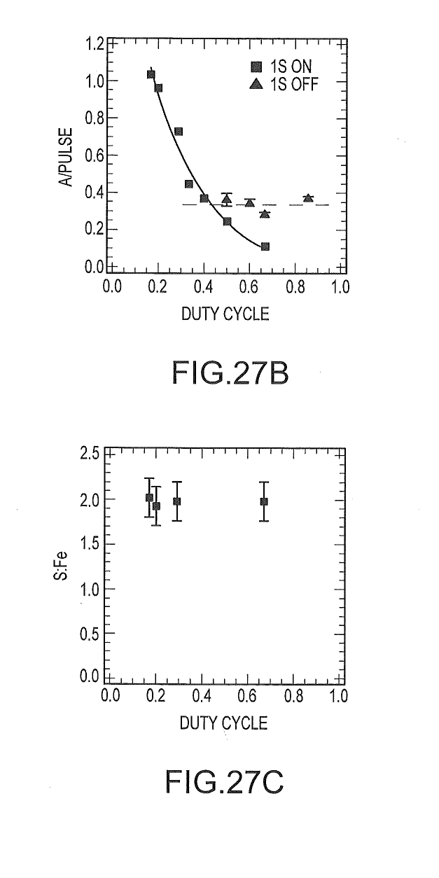

The self-limiting nature of the pulsed PECVD process is confirmed by first observing that no thermal CVD occurs with a continuous delivery of both reactants at a temperature of about 240° C. in the absence of plasma. Likewise, no deposition is observed during CW plasma operation over the power range explored, which was between about 15 W to about 100 W. Images of the FTO glass substrates from these experiments are illustrated in FIG. 27A. Under the same reactor conditions, pulsing the plasma at a duty cycle of about 0.5 produces the strongly absorbing iron disulfide film illustrated in FIG. 27A.

The importance of duty cycle on rate and quality is examined by fixing either the tₒₙ or t_{off} at about 1 second, and varying the other parameter. The substrate temperature and RF power are fixed at about 240° C. and about 50 W, respectively. FIG. 27B illustrates the relationship of deposition rate with duty cycle. With tₒₙ of about 1 second, the growth per cycle (GPC) increases from about 0.01 nm/pulse to about 0.1 nm/pulse as duty cycle is reduced from about 0.67 to about 0.17. In contrast, with t_{off} fixed at about 1 second, the GPC is essentially independent of duty cycle at a value of about 0.034 nm/pulse. The insensitivity of GPC to plasma on time suggests that plasma consumption of IPC is very fast (much less than 1 second) and that the plasma exposure step is primarily for removing ligands and producing stoichiometric films. The GPC value is controlled by the plasma off time, and the dependence is consistent with the residence time of the reactor. Based on the volumetric flowrate and estimates of the chamber volume, the residence time was about 2 seconds. At plasma extinction, the density of IPC in the reactor is negligible. By approximating the low pressure reactor as a well mixed reactor, the time required for IPC concentration to reach steady state level is estimated to be between about 5 seconds to about 10 seconds. The IPC concentration in the reactor at plasma ignition controls the amount of precursor available for deposition.

FIG. 27C illustrates the stoichiometry as duty cycle is varied for films with a thickness of at least about 100 nm. Within the accuracy of the techniques, all pulsed PECVD films display the stoichiometric 2:1 sulfur to iron ratio, independent of process conditions. Neither carbon nor oxygen are detected beyond background levels that were observed in all samples including the pyrite calibration standard.

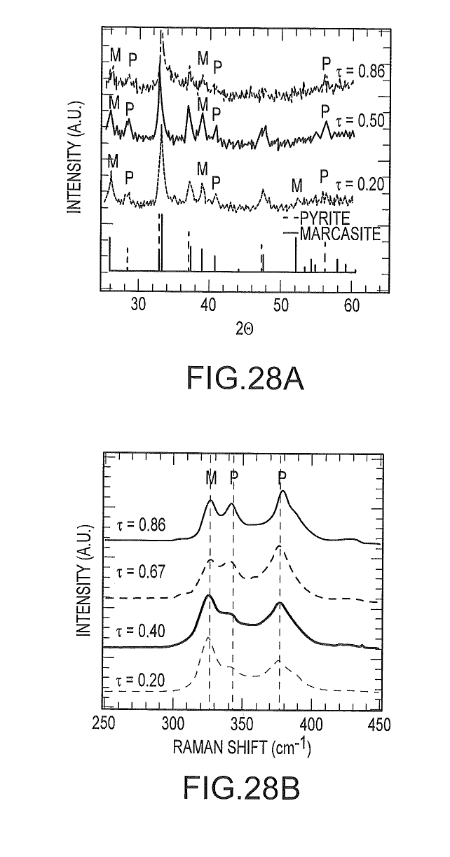

The crystal phases present are evaluated by XRD and Raman spectroscopy with selected results illustrated in FIG. 28A. The duty cycle is varied from 0.20 (t_{off}=4 s, tₒₙ=1 s) to 0.86 (t_{off}=1 s, tₒₙ=6 s), with the duty cycle at 0.5(t_{off}=1 s, tₒₙ=1 s). The XRD patterns illustrate a mixture of pyrite and marcasite, but no substoichiometric compounds are detected. While pyrite and marcasite have several overlapping peaks, pyrite can be distinguished by its reflections at about 28.5° (111) (Miller indices denoted in parentheses), about 40.7° (211), and about 56.3° (311). Likewise, unique marcasite reflections appear at about 25.9° (110), about 39.0° (120), and about 52.0° (211). Comparison of these peaks at different duty cycles illustrates that the pyrite fraction is enhanced with increasing duty cycle. This trend is confirmed by the Raman spectra illustrated in FIG. 28B. The dominant bands observed are the E_{g} and A_{g} modes for pyrite at about 343 cm⁻¹ and about 377 cm⁻¹, respectively, and the A_{g} mode for marcasite at about 326 cm⁻¹. The marcasite bands decrease relative to pyrite bands as duty cycle is increased from about 0.20 to about 0.67. However, further increasing the duty cycle beyond 0.67 does not appreciably change the pyrite to marcasite ratio. In addition, the impact of post-deposition sulfurization is examined by exposing films to an H₂S plasma for an hour at about 400° C. This treatment reduces the marcasite content for films that have a large marcasite fraction in the as-deposited state, but it has no detectable impact on films that originally contain a low marcasite fraction.

The substrate temperature is varied between about 40° C. and about 380° C. with the plasma power and duty cycle held constant at about 50 W and about 0.67, respectively. At the lowest temperature of about 40° C. (sulfur vapor pressure less than about 0.1 Pa), the substrate is covered by crystallized sulfur, confirming that the plasma is effective for dissociating H₂S.

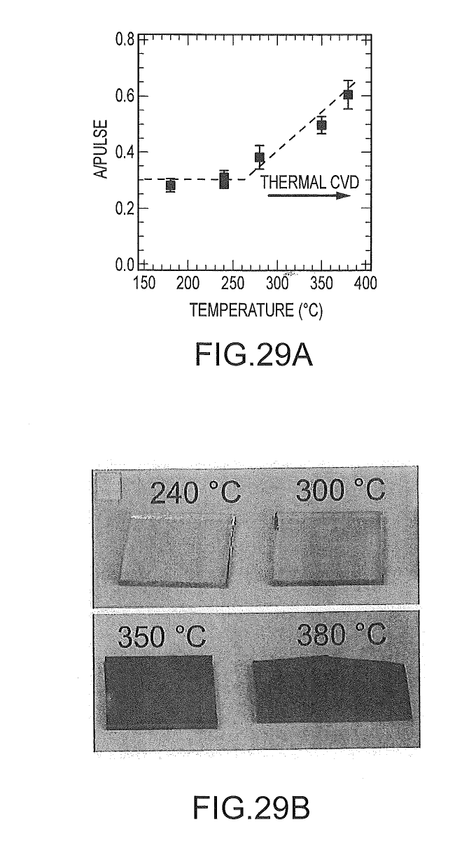

FIG. 29A illustrates growth per cycle as a function of temperature for temperatures between about 180° C. and 380° C., conditions where no sulfur condensation is observed. Below about 280° C., the GPC is constant at about 0.03 nm/pulse, but above this point the growth per cycle increases linearly with substrate temperature. This increase is attributed to the onset of thermal CVD contributions to growth. This increase is verified by thermal CVD experiments as a function of temperature. FIG. 29B illustrates photographs of substrates after exposure to reactants at selected substrate temperatures. These photographs indicate that the critical temperature for the onset of thermal CVD occurs at about 300° C., at which point a faint film is observed after exposure to the reactants for about 15 minutes. The onset of thermal CVD is in good agreement with pulsed PECVD data. At and above about 350° C., a very distinguishable and thick film is formed. The onset of thermal CVD observed is greater than the about 150° C. reported in previous studies using IPC and H₂S. Though not wanting to be bound by theory, the differences in reactor pressure may explain the thermal CVD as previous studies were performed at about atmospheric pressure or about 660 Pa, which is about 12 times greater than the pressure used in this experiment.

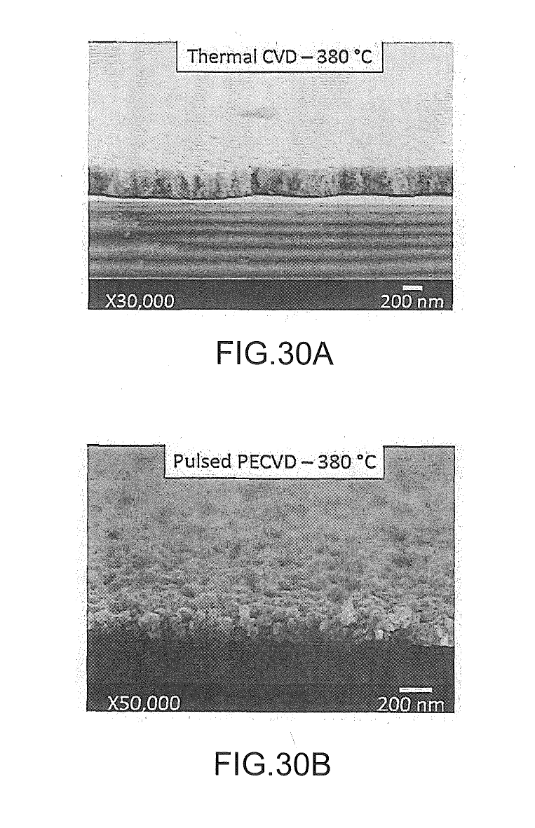

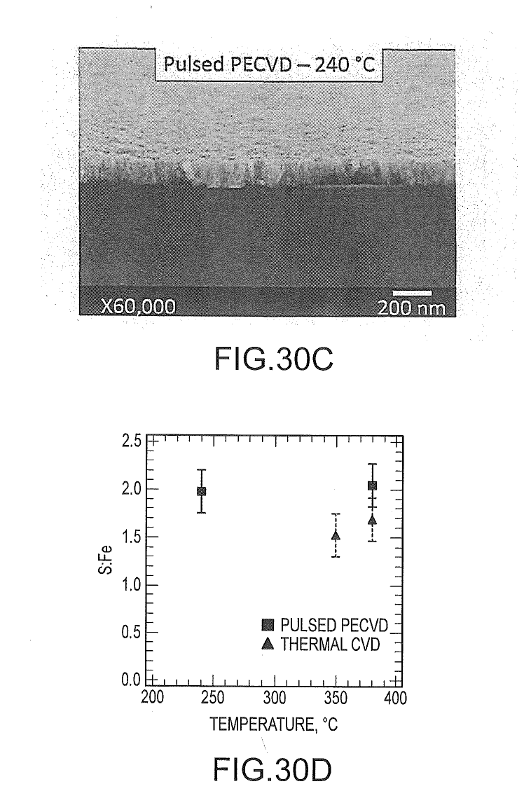

The impact of thermal CVD contributions to the morphology and stoichiometry of the films as a function of temperature is evaluated by FESEM and EDAX. FIGS. 30A, 30B, 30C, and 30D compare representative FESEM images of the morphology obtained from the three deposition regimes: (i) thermal CVD; (ii) pulsed PECVD at T>300° C.; and (iii) pulsed PECVD at T<300° C. Films produced by thermal CVD are very smooth with a homogeneous, nanocrystalline grain structure, as illustrated in FIG. 30A. In contrast, films produced at the same temperature by pulsed PECVD had a significantly different morphology, as illustrated in FIG. 30B. These films are significantly rougher, with larger, randomly oriented crystal grains clearly visible. FIG. 30C illustrates a pulsed PECVD film at about 240° C., i.e. less than or equal to the critical temperature, which displays a columnar grain structure and is quite smooth compared to the pulsed PECVD film at about 380° C. Within a deposition regime, the morphology variations are not significant. The differences between thermal CVD and pulsed PECVD films are also manifested in film composition as illustrated in FIG. 30D. The composition of all pulsed PECVD films, regardless of temperature, is stoichiometric within measurement error. In contrast, all thermal CVD films displayed substoichiometric compositions with sulfur to iron ratios ranging from about 1.5 to about 1.7.

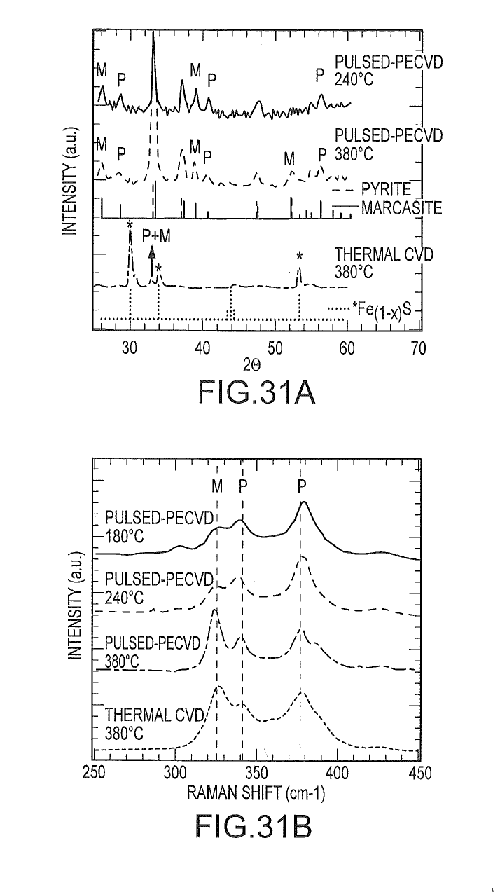

The differences in composition between thermal CVD and pulsed PECVD films are further corroborated by the XRD patterns illustrated in FIG. 31A. Only weak reflections of pyrite and marcasite are observed in the XRD pattern from the thermal CVD material, the most noticeable of which are at 2θ=33.0° and 33.3° corresponding to the pyrite (200) and marcasite (101) planes, respectively. However, the pattern is dominated by reflections at 2θ=30°, 33.8°, and 53.3°, which correspond to the (122), (004), and (522) planes of pyrrhotite (Fe₁₋ₓS, x=0-0.2). Another strong reflection for pyrrhotite is expected for the (040) plane at about 43.2°, which suggests that the pyrrhotite displays a preferred crystal orientation. In contrast, under the same process conditions with pulsed PECVD, nonstoichiometric compounds are no longer present and only pyrite and marcasite signals are observed. The pulsed PECVD film at about 240° C. also has both marcasite and pyrite phases detected by XRD, but the marcasite fraction is the greatest at about 380° C. where thermal CVD contributes to growth. This trend is supported by the Raman spectra illustrated in FIG. 31B. Below the critical temperature of 300° C., the strongest intensity is from the vibrational modes of pyrite, whereas the marcasite band at about 326 cm⁻¹ dominates the spectra above the critical temperature. Though only weak reflections are observed by XRD, Raman displays signals that confirm the presence of pyrite and marcasite phases in the thermal CVD film. These results clearly demonstrate the benefits of plasma processing. Thermal CVD favors formation of marcasite and Fe₁₋ₓS phases, while the addition of plasma eliminates Fe₁₋ₓS and enables operation at lower substrate temperatures to reduce the marcasite fraction.

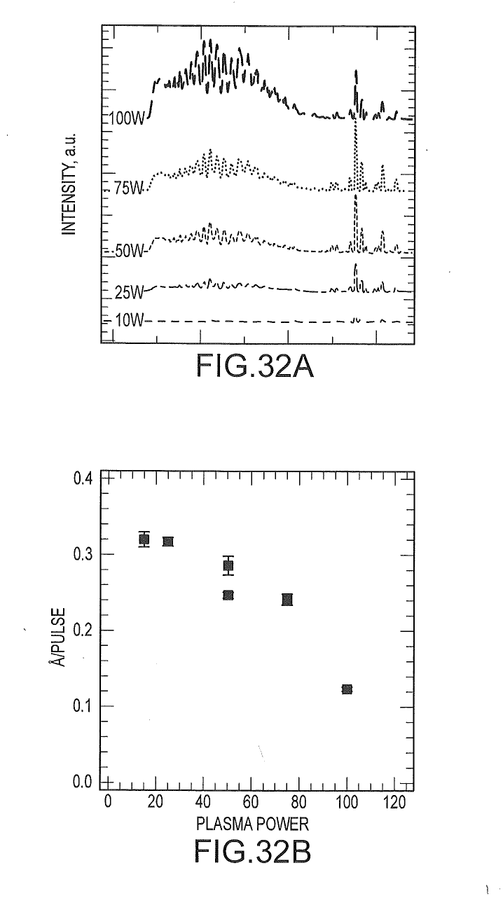

Plasma power is varied from about 15 W to about 100 W with the substrate temperature and duty cycle fixed at about 240° C. and 0.67, respectively. FIG. 32A illustrates the spectra collected by an optical emission spectrometer at different RF power. The strong bands between about 300 nm and about 600 nm are associated with emission from sulfur dimers while the emission lines between about 650 nm and about 850 nm are associated with argon. Weak peaks associated with iron and CO⁺ at about 375 nm and about 428 nm, respectively, are observed in IPC/argon plasmas, but are no longer distinguishable when H₂S is added. As the RF power is increased, the overall plasma intensity increases. The intensity ratio of the dominant sulfur-related peak (about 420 nm) relative to the argon peak at about 750 nm gradually increases from about 0.26 to about 0.59 as plasma power increases from about 10 W to about 75 W, and sharply increases to about 1.7 as power further increases to about 100 W. This suggests that the level of H₂S dissociation and thus sulfur activity scales with RF power. FIG. 32B illustrates the relationship of deposition rate with plasma power. Increasing the power causes a decrease in deposition rate between about 15 and about 75 W, with a sharp drop off in rate between about 75 W and about 100 W. The decrease in rate is attributed to increased gas-phase consumption of IPC derived precursors, and coincides well with the trends observed by OES.

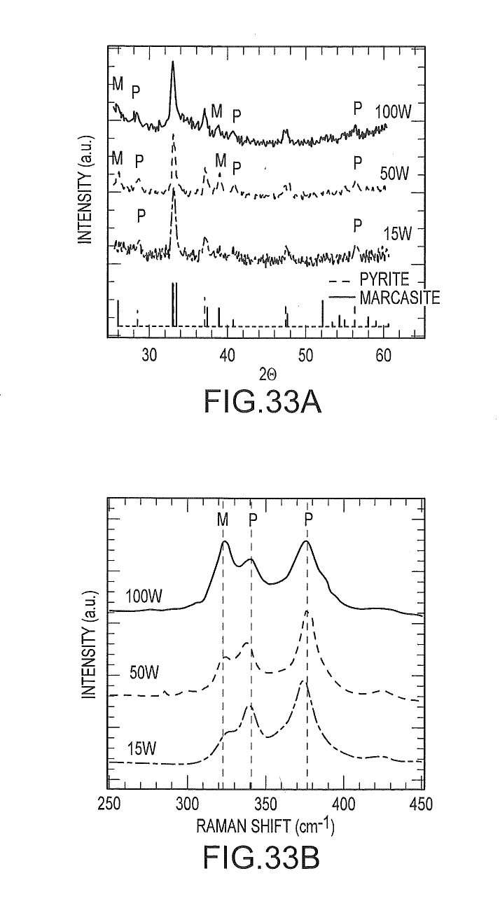

FIGS. 33A and 33B illustrate both XRD and Raman characterization of films deposited as a function of plasma power. Both display that the marcasite phase increases with plasma power. At about 15 W, marcasite is not detectable by XRD and only a small shoulder at about 326 cm⁻¹ is observed with Raman. This condition produces the most phase pure pyrite within the range of all process parameters. This finding is somewhat counterintuitive. As illustrated in FIGS. 28A and 28B, increasing plasma exposure time through increasing duty cycle is found to be beneficial for the pyrite component. Likewise, the presence of plasma mitigates impurities produced through thermal CVD, as illustrated in FIGS. 31A and 31B. One plausible explanation for this trend is that the sulfur species (S, S₂) generated by plasma activation of H₂S are beneficial for forming FeS₂, but that excessive exposure to the other excited species generated by the plasma such as electrons, ions or atomic hydrogen may be detrimental to pyrite formation. The bombardment and/or recombination of these species on the growing surface may induce damage or lead to localized heating. This would be consistent with the observation that higher substrate temperature favors marcasite.

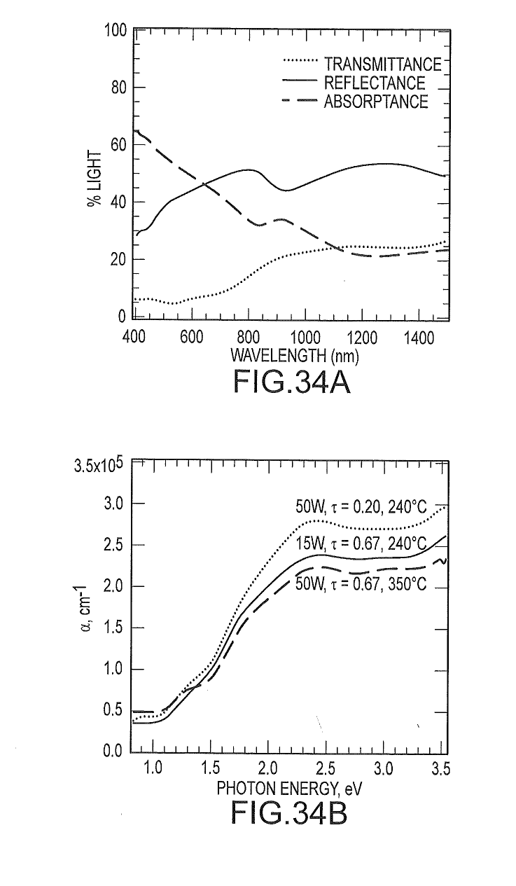

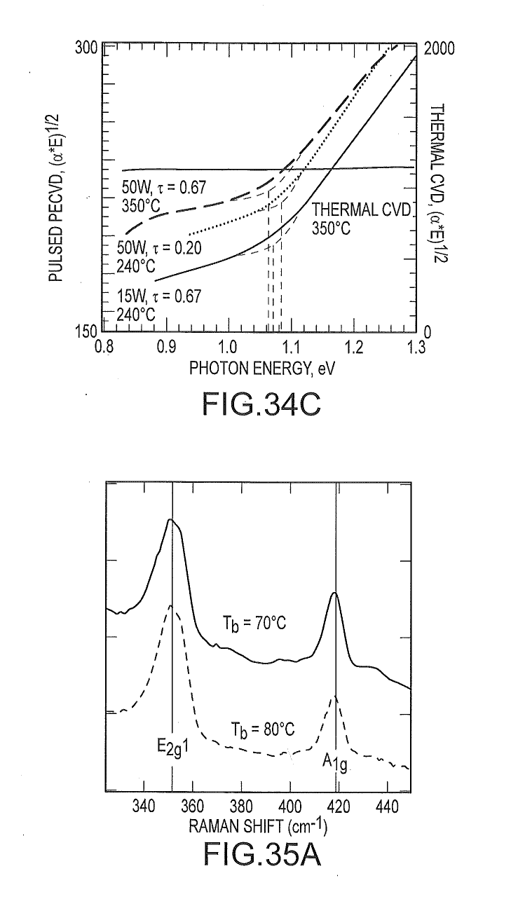

The optical characteristics of all films produced are examined. FIGS. 34A, 34B, and 34C illustrate optical properties of a representative selection of films. These samples include pulsed PECVD films with varying pyrite to marcasite ratios. The solid line in the graph represents low marcasite, the dotted line represents high marcasite and the dashed line represents intermediate marcasite. FIG. 34A illustrates spectra representative of pulsed PECVD films, which are obtained at about 50 W, Tₛ=240° C., and τ=0.67. All pulsed PECVD films display a high level of reflection near about 50%. Reflection-corrected absorption coefficients are plotted as a function of photon energy illustrated in FIG. 34B. Despite significant variation in phase purity, the pulsed PECVD films all display very similar properties with absorption coefficients of about 10⁵ cm⁻¹ for hv>about 1.5 eV, regardless of the process conditions. Thermal CVD films are not included as they do not show any band edge or features expected of a semiconductor. The optical band gap is extracted assuming an indirect transition, as illustrated in the plot of (αE)^{1/2} versus photon energy. As illustrated in FIG. 34C, the optical band gap is estimated by the intersection of the two linear regions of these curves. FIG. 34C also illustrates the analysis of a thermal CVD film, which is the horizontal line with no specific absorption features. For all FeS₂ films the indirect band gap is determined to be about 1.06±0.03 eV, independent of pulsed PECVD process conditions. The band gap values are consistent with the range of indirect band gaps reported in previous pyrite studies of about 0.9 eV to about 1.1 eV. Neither the band gap nor the absorption coefficients are appreciably impacted by the ratio of pyrite to marcasite. Recent density-functional theory calculations suggest that marcasite has a band gap no less than pyrite, and that assertion is supported.

### Example 4

### Pulsed PECVD with Tungsten Hexacarbonyl and Hydrogen Sulfide Precursors to Form Tungsten Sulfide

### Forming the Samples

The metal precursor is tungsten hexacarbonyl [W(CO)₆], the chalcogen vapor precursor is hydrogen sulfide (H₂S), and the vapor mixture is tungsten sulfide (WS₂).

The deposition chamber consists of capacitive-coupled parallel plate reactor. Plasma is generated by an about 13.56 MHz RF source and a custom matching network is used to minimize reflected power. Precursors are pre-mixed and delivered to the chamber through an about 13.9 cm diameter showerhead, which also serves as the powered electrode. Flow of W(CO)₆ is controlled using a bubbler controlled to about 450 Torr, and the argon carrier gas flowrate is set to about 32 sccm using an MFC. The temperature of the bubbler, T_{b}, is set tested at about 80° C. and about 70° C. to achieve W(CO)₆ flow rate of about 0.21 and about 0.10 sccm, respectively. Hydrogen sulfide gas diluted to about 10% in argon is controlled by an MFC set to about 150 sccm. A third stream of argon set to 100 sccm is used to raise the reactor pressure to about 400 mTorr. Table 2 summarizes the baseline conditions and parameter space.

TABLE 2

| Parameter | Baseline | Range |
|---|---|---|
| Duty cycle (τ) | 0.67 | 0-1 |
| Substrate temperature (° C.) | 400 | 320-425 |
| RF power (W) | 100 | 30, 100 |
| W(CO)₆ flowrate (sccm) | 0.21 | 0.10, 0.21 |
| W(CO)₆ partial pressure (p_{W}, mTorr) | 0.30 | 0.30, 0.60 |
| W(CO)₆ concentration (c_{W}) | 0.074% | 0.037%, 0.074% |
| H₂S:W(CO)₆ ratio | 71 | Fixed |
| Pressure (mTorr) | 400 | 400, 800 |

Substrates consist of silicon wafers and FTO coated glass, and have a nominal size of about 3.5 cm×3.5 cm. The native oxide of the silicon is removed by dipping in about 2% HF and FTO glass is sonicated for about 5 minutes in Alconox solution, then sequentially rinsed with deionized water, acetone, and methanol. Substrates are attached to the grounded electrode located about 5.7 cm above the showerhead. Substrates are heated with a resistance heater and temperature monitored with a thermocouple located outside of the reactor. An OES is attached to the outside of the reactor to monitor the plasma emission spectrum through a site glass.

### Testing of the Samples

Raman spectroscopy is performed using a WITec Alpha 300R Confocal Raman Microscope at an excitation wavelength of about 532 nm and about 100× magnification. Analysis is performed on films deposited onto silicon and spectra are centered to the about 520 cm⁻¹ silicon peak. X-ray diffraction is performed on films deposited on silicon substrates with a Siemens D500 diffractometer using Cu Kα (λ=0.154 nm) X-ray source. Absorption coefficients are calculated from transmittance measured using a Cary 5G UV-Vis-NIR photospectrometer, which is corrected for background and reflectance. FESEM, model JEOL JSM-7000F, is used to image the top of films and to measure cross-section thickness. An EDAX unit attached to the FESEM is used to determine the ratio of tungsten and sulfur. EDAX is measured using an about 5 kV accelerating voltage and is calibrated to a WS₂ standard. Transmission electron microscope (TEM) images are performed using a Philips (FEI) CM200 TEM. Samples for TEM are prepared by scraping powder off the substrate and dispersing into ethanol, which is then deposited onto a copper grid. Polarization curves are measured using Gamry PCI4 Potentiostat at a scan rate of about 5 mV/s. Films deposited on FTO coated glass serve as the working electrode with a platinum mesh used as a counter electrode. The electrolyte is about 0.5 M H₂SO₄ and a Ag/AgCl electrode serves as a voltage reference. Voltage is correct for pH and reported versus the RHE. The onset potential is determined by first fitting current density data between about 0 and about -0.05 V vs RHE to a linear plot. The voltage at which measured current density is greater than about 0.5 mA/cm² from the linear plot is reported as the onset over potential.

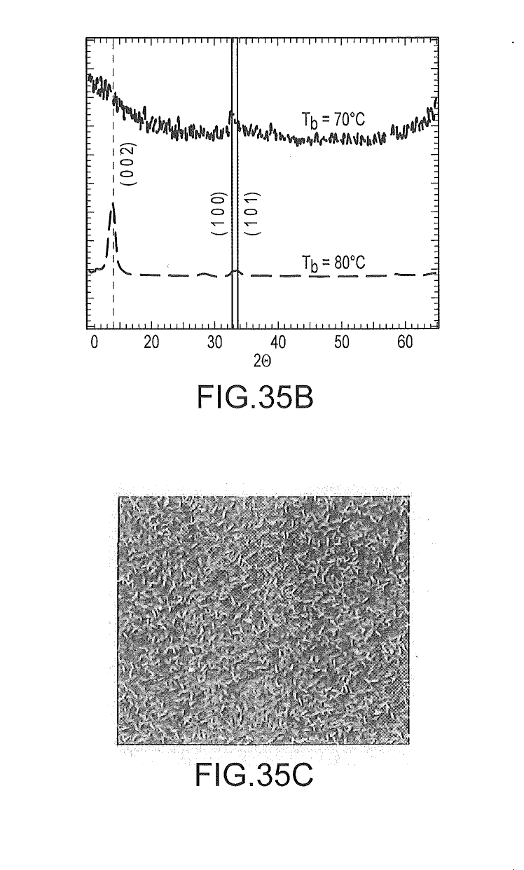

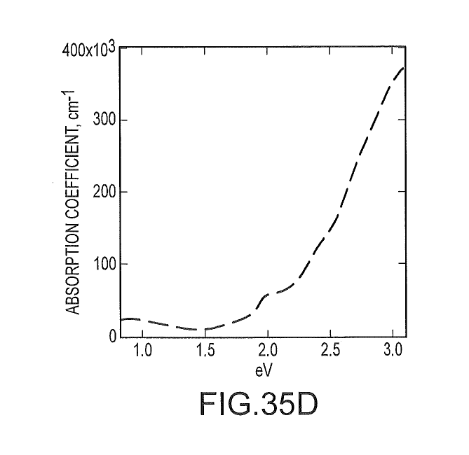

W(CO)₆ source temperatures are tested, corresponding to W(CO)₆ flow rates of about 0.10 sccm and about 0.21 sccm, respectively. Reactor conditions were fixed at about 400° C., about 400 mTorr, about 100 W, and a duty cycle of 0.67 (about 1 second on, about 2 seconds off). Both temperatures produce a film and the growth rates for both films are similar, about 0.07 nm/pulse. Films are characterized first by Raman, with spectra illustrated in FIG. 35A. Both films are identified as WS₂ by the two dominant modes, the E_{2g}¹ mode at about 352 cm⁻¹ and A_{1g} mode at about 419 cm⁻¹, and no other phases are observed. Films are then further characterized by XRD. FIG. 35B illustrates the XRD patterns of these two films. The film deposited at about 80° C. has a strong reflection at about 14.4°, which is identified as the (002) plane for WS₂. Two additional, overlapping reflections at about 32.8° and about 33.6° are identified, corresponding to the WS₂ (100) and (101) planes. However, these two reflections are much smaller than the (002) plane. The strong intensity of the (002) plane compared to the (100) and (101) planes indicate that the WS₂ sandwich layers are preferentially oriented parallel to the substrate. For simplicity, orientation of layers parallel to the substrate ((002) plane) are referred to as CH, and non-parallel orientations (100) and (101) planes) are referred to as C(∥). The film deposited at about 70° C. had no reflection at about 14.4°. There is a reflection at about 33°, corresponding to (100)/(101) planes and supports the presence of WS₂, though the poor signal to noise ratio is indicative of poor crystal quality or the presence of amorphous material.

The film deposited at about 80° C. is further characterized and the morphology is illustrated in the FESEM image illustrated in FIG. 35C. The film is composed of narrow platelets that are about 50 nm in width. Similar morphologies for thin film WS₂ have been reported by CVD and reactive sputtering studies. EDAX is used to determine that the sulfur to tungsten ratio of the film is stoichiometric (2.0:1±0.1). FIG. 35D illustrates the absorption coefficient of the film characterized by UV-Vis-NIR. The film has a strong absorption coefficient, which is greater than 10⁵ cm⁻¹ for E≧2.3 eV. The film displays an excitonic feature at about 2 eV and a subtle feature at about 2.5 eV that is characteristic of WS₂. For the other films produced the W(CO)₆ flow rate is set to about 0.21 sccm, given the preferred crystalline nature of the film as indicated by XRD and the suitable stoichiometry and absorption spectra.

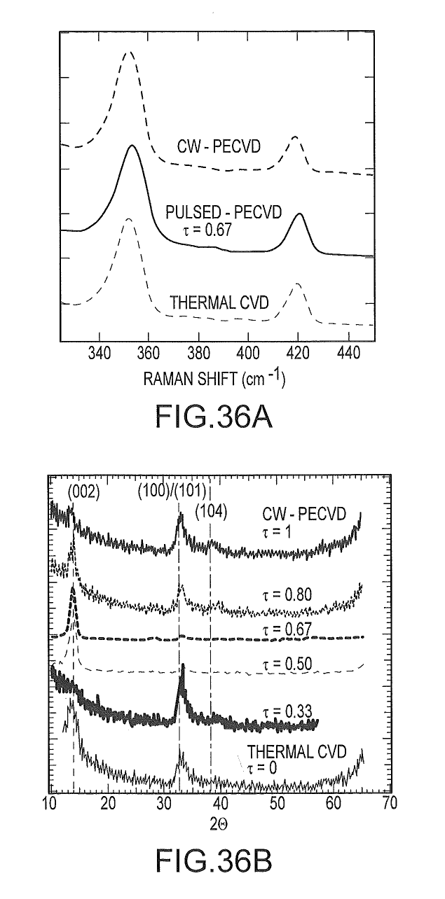

Duty cycle is varied between about 0.33 and about 0.80 with fixed reactor parameters of about 400° C., about 100 W, and about 400 mTorr, and deposition time is set to produce film thicknesses near 50 nm. Thermal CVD and CW-PECVD are also tested at these conditions, which are equivalent to τ of about 0 and τ of about 1, respectively. Both thermal CVD and CW-PECVD result in film deposition and FIG. 36A illustrates the Raman spectra of these compared to τ of about 0.67. All three Raman spectra show the two WS₂ modes at about 352 cm⁻¹ and about 419 cm⁻¹ with no significant differences and no other phases detected. This similarity in Raman spectra is observed for other duty cycles as well. XRD is most sensitive at distinguishing physical differences and if WS₂ is detected by XRD, the Raman spectra of the film appears similar to those illustrated in FIG. 36A. FIG. 36B illustrates the XRD patterns of films as a function of duty cycle. Both the thermal CVD and CW-CVD films have WS₂ reflections for (002) and (100)/(101). A smaller reflection at about 38.2° is also observed, which corresponds to the (104) plane. The comparable intensities of (002) and (100)/(101) indicate a mixture of C(=) and C(11) orientations. In stark contrast are the films deposited by pulsed-PECVD at τ of about 0.50 and τ of about 0.67, which are dominated by C(=) orientation, and these display improved signal to noise that indicate better crystal quality. Also illustrated in FIG. 36B are the XRD patterns for τ of about 0.33 and τ of about 0.80, which show reflections for WS₂, but with either a mixture of C(=)/C(∥) or a preferred C(1). Duty cycle also affects growth rate. The deposition rates for duty cycles between about 0 and about 0.33 and duty cycles between about 0.80 and about 1 are more than 2 nm/min. For duty cycles between about 0.50 and about 0.67, the growth rate is reduced to about 1.5 nm/min to about 1.7 nm/min (about 0.07 nm/pulse), which may be in part responsible for the improved crystallinity.

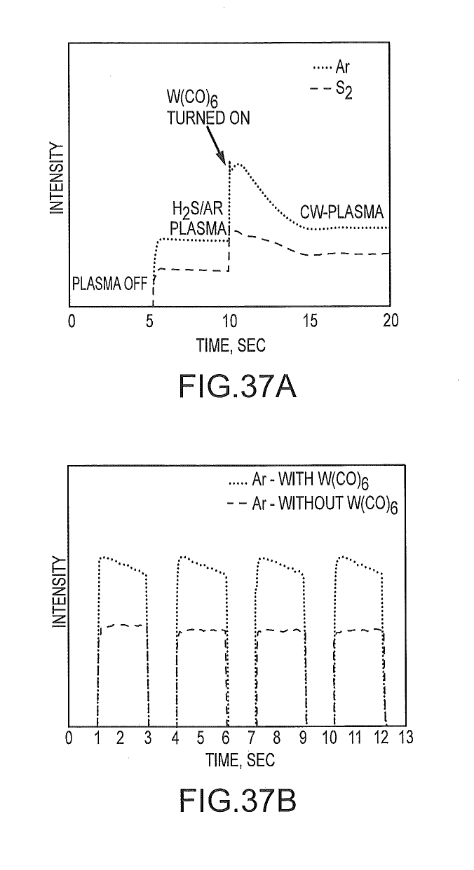

An OES is used to characterize the plasma. The primary emission from the plasma is composed of argon lines in the range of about 650 nm to about 850 nm and S₂ bands between about 300 nm and about 600 nm, with no other chemical species distinguishable. FIG. 37A illustrates the transient behavior for two wavelengths: the strongest argon line at about 750 nm and the strongest of the S₂ band centered at about 420 nm. In this scan, plasma ignition occurs at about 5 seconds. Between about 5 seconds and 10 seconds, the plasma is composed of only H₂S and argon and no W(CO)₆ is flowing to the reactor. At ignition, the plasma quickly stabilizes within about 0.5 seconds. At about 10 seconds, W(CO)₆ is introduced to the plasma. The metal precursor has a profound effect, doubling the plasma intensity. The intensity then slowly decreases and it takes a full about 5 seconds for the plasma to stabilize, an amount of time notably greater than the typical plasma on time. When the plasma stabilizes at about 15 seconds, the intensity is still greater than in the plasma without W(CO)₆. The steady state plasma at greater than or equal to about 15 seconds is representative of CW-PECVD. FIG. 37B illustrates the plasma intensity of argon under pulsed-PECVD at τ of about 0.67 (about 2 seconds on, about 1 second off) with and without W(CO)₆. When the W(CO)₆ is not flowing, the intensity is relatively constant for the about 2 seconds pulse. When W(CO)₆ is flowing, there is a spike in plasma intensity at ignition followed by a decrease in intensity over about 2 seconds. The plasma during each approximate 2 second pulse from FIG. 37B is best represented on FIG. 37A by the intensity between about 10 seconds and about 12 seconds. This period of high plasma activity is sustained in a pseudo-steady state created by pulsing that cannot be maintained by CW-plasma.

There are two potential causes for the improved crystallinity and preferred orientation at τ of about 0.67. First, the plasma intensity is greatest immediately after ignition, and this could lead to better annealing of the film. Another possibility is that the gas phase is composed of transient intermediate species, W*, formed after during ignition that are not present in appreciable quantities under steady-state CW-plasma and enables deposition to occur under a different reaction pathway. The sulfurization of W* might be occurring partially in the gas phase rather than after it is deposited on the substrate.

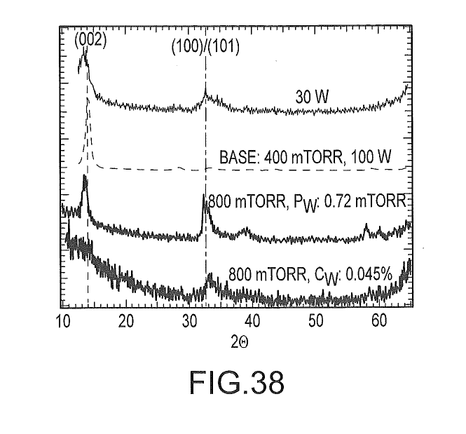

The impact of pressure and plasma power are also explored with the duty cycle and temperature fixed at about 0.67 and about 400° C., respectively. Power is tested at about 30 W, with pressure set at the base condition of about 400 mTorr. FIG. 38 illustrates the XRD pattern and illustrates the reflection at about 14.4° is still stronger than at about 33°, but the difference is not as significant as at about 100 W. The reduced signal and peak broadening of about 14.4° at about 30 W when compared to about 100 W indicate that the film at lower power is less crystalline. The growth rate is still about 0.07 nm/pulse, similar to about 100 W. Pressure is then explored at about 800 mTorr with power set at base about 100 W. The result of increasing the pressure of plasma is more collisions, which increase density of energetic species but reduce their average energy. The XRD pattern from this experiment is illustrated in FIG. 38. At about 800 mTorr, the (002) and (100)/(101) reflections are of similar orders of magnitude. The growth rate for this condition is doubled to about 0.14 nm/pulse and may be partly contributing to the change in orientation. The increased growth rate at about 800 mTorr versus about 400 mTorr is most likely due to an increase in W(CO)₆ partial pressure, from p_{w} of about 0.30 mTorr to p_{w} of about 0.60 mTorr, with W(CO)₆ concentration constant, c_{w} of about 0.074%. Additionally, dilution with argon is conducted to maintain the partial pressure at pw of about 0.30 mTorr, and decrease the W(CO)₆ concentrations from c_{w} of about 0.074%, down to c_{w} of about 0.037%. This reduces the growth rate to about 0.06 nm/pulse. However, the XRD pattern of this film illustrates no distinguishable reflection at about 14.4° and only a weak reflection at about 33°. Reducing W(CO)₆ concentration also reduces the increased plasma intensity at ignition. The concentration of W(CO)₆ is an important parameter, which directly affects the plasma intensity and drives C(=) orientation and improved crystallinity, while increasing power also contributes to these attributes.

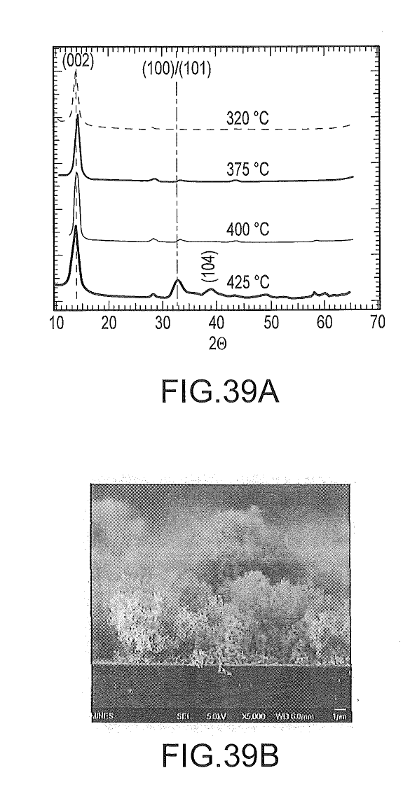

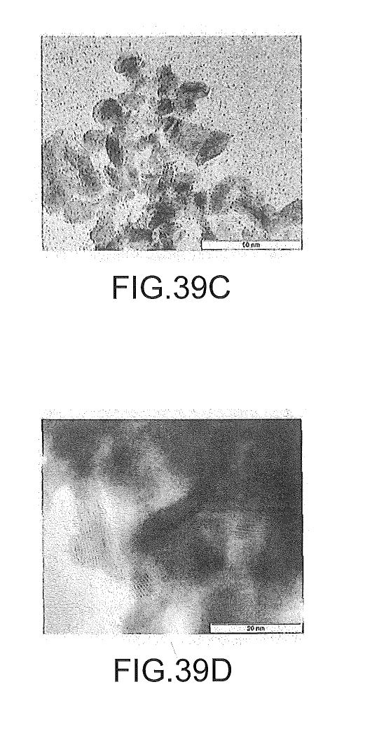

Substrate temperature is varied from about 320° C. to about 425° C. with duty cycle, pressure and power fixed at about 0.67, about 400 mTorr, and about 100 W, respectively. The onset of thermal CVD is illustrated to occur at about 330° C. For pulsed-PECVD at about 320° C., deposition is driven by the plasma only and no thermal CVD occurs during the plasma-off time. The impact of this on pulsed-PECVD experiments is most immediately seen by reduced growth rate, from about 0.07 nm/pulse at about 400° C. to about 0.04 nm/pulse at about 320° C. The XRD patterns for these films are illustrated in FIG. 39A. As temperature is reduced from about 400° C. down to about 320° C., the XRD spectra remain mostly unchanged with the reflection at about 14.4° still dominant. These results contrast with films produced by thermal CVD, where temperature is found to be the most important parameter for controlling film orientation. At higher temperature, about 425° C., films resort to a random orientation as the reflections for the (100)/(101) planes increased.

At this elevated temperature a residue is observed on the substrate after deposition. Imaging of the residue, illustrated in FIG. 39B, reveals the presence of a nanopowder on the surface. The powder is confirmed to be stoichiometric WS₂ by EDAX. The mixed orientation of the powder most likely dominates the XRD patterns. TEM images of the powder are illustrated in FIG. 39C, revealing small crystallites that are between about 5 nm and about 20 nm in size. At larger magnification, as illustrated in FIG. 39D, the image illustrates a layered, crystalline structure consistent with WS₂. Nanoparticles are of similar size and appearance as those made by Vollath and Szabo, who used a microwave plasma with the same precursors, W(CO)₆ diluted H₂S/argon. Those nano-particles were produced at much lower temperature, as low as about 160° C., but also higher pressures, at least about 7.6 Ton. The higher pressure is more conducive for gas phase reaction and nucleation and explains why nanoparticles were produced at lower temperatures.

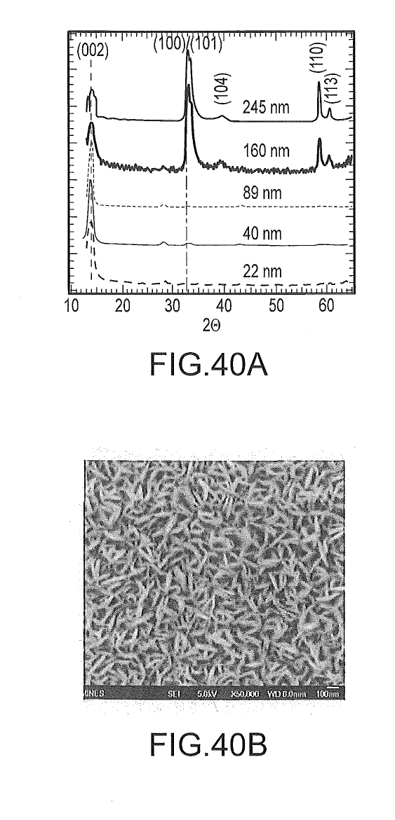

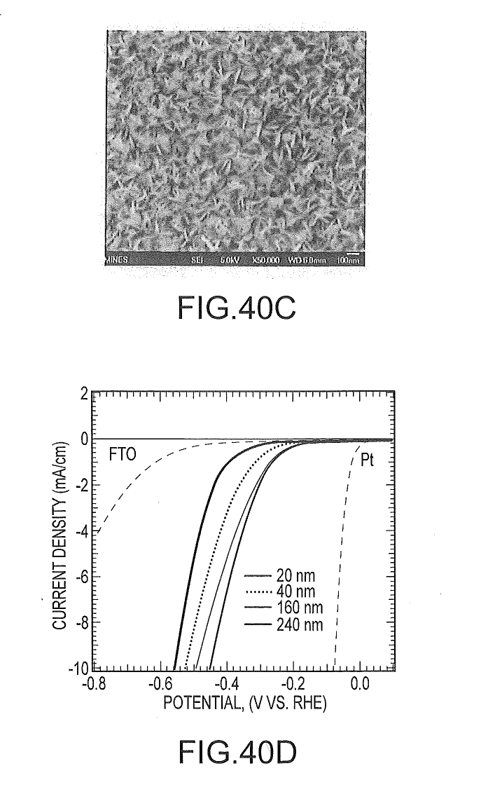

Film thicknesses are nominally deposited at about 50 nm to best compare the effects of reactor parameters. To determine the influence of thickness as a parameter, a series of films are deposited between about 20 nm and about 240 nm at τ to about 0.67, about 100 W, Tₛ to about 400° C., and about 400 mTorr. XRD for these films are illustrated in FIG. 40A. The dominant reflection at about 14.4° for film thicknesses between about 20 nm and about 90 nm illustrates that C(=) continues as the preferred orientation in this range. As thickness is further increased to about 160 nm and about 240 nm, the orientation changes to a non-parallel orientation, C(11). FIG. 40B illustrates an image of the about 240 nm film, which illustrates a high density of platelets oriented upwards with larger feature sizes than when first nucleated as in FIG. 35C. FIG. 40C is an image of the about 89 nm film, which illustrates a morphology between about 22 nm, as illustrated in FIG. 35C, and about 240 nm. Similar observations of transition from C(=) to C(1) orientation with increased film thickness have been observed for reactive sputtering of WS₂ and thermal CVD of WS₂ and MoS₂. As defects form, growth occurs non-parallel to the substrate and growth is accelerated along the edge portion of the planes.

Films deposited on FTO from the thickness series are tested for a potential application as an HER catalyst, to determine the influence of orientation on the onset potential. Polarization curves for these different films are illustrated in FIG. 40D and are compared to platinum and FTO, which serve as highly active and inert reference surfaces. The lowest over-potential to achieve hydrogen evolution is platinum, about 30 mV. For bare FTO, the over-potential is about 550 mV and is reduced to about 340 mV with about 20 nm of WS₂. The over-potential is further reduced to about 240 mV as thickness increases to about 240 nm and orientation changes from C(=) to C(1). The active portion of WS₂ for catalyst is the edge sites, and an improvement in over-potential is most likely due to increase density of these sites. Best results for WS₂ HER onset over-potentials are between about 100 and about 200 mV. One of the most successful techniques for exposing edge sites is multi-step, where after WS₂ is produced, it is then exfoliated to make nano-flakes and then depositing onto a substrate. The exfoliation process serves both to increase exposed edge sites and create lattice strain that increases activity. While the onset over-potential is greater for pulsed-PECVD, it does produce electrocatalytic active surface for very thin films, less than about 300 nm, and demonstrates the potential benefit of orientation.

The foregoing description of the present invention has been presented for purposes of illustration and description. Furthermore, the description is not intended to limit the invention to the form disclosed herein. Consequently, variations and modifications commensurate with the above teachings, and the skill or knowledge of the relevant art, are within the scope of the present invention. The embodiment described hereinabove is further intended to explain the best mode known for practicing the invention and to enable others skilled in the art to utilize the invention in such, or other, embodiments and with various modifications required by the particular applications or uses of the present invention. It is intended that the appended claims be construed to include alternative embodiments to the extent permitted by the prior art.

1. A method of forming a metal chalcogenide coated substrate, the method comprising:
depositing a layer comprising a metal oxide onto a substrate to create a coated substrate;
exposing the coated substrate to a temperature of between about 200° C. to about 600° C. to create a heated coated substrate; and
exposing the heated coated substrate to an elemental chalcogenide to convert the metal oxide in the layer to a metal chalcogenide.

2. The method of claim 1, wherein the metal oxide is at least one of a molybdenum oxide, an iron oxide, a tungsten oxide, a titanium oxide, and a niobium oxide.

3. The method of claim 1, wherein the elemental chalcogenide at least one of a sulfur, a selenium, a tellurium, and a polonium.

4. The method of claim 1, wherein the layer is deposited onto the substrate by one or more of a vapor deposition, a sputtering, and an atomic layer deposition.

5. The method of claim 1, wherein a thickness of the layer is between about 1 nm and about 200 nm.

6. The method of claim 1, wherein a thickness of the layer is applied is different from a thickness of the layer after the metal oxide is converted to the metal chalcogenide.

7. The method of claim 1, wherein the coated substrate is exposed to the elemental chalcogenide for between about 1 minute and about 60 minutes.

8. A method to produce a metal chalcogenide coated substrate, the method comprising:
mixing a vapor phase metal precursor with a chalcogen vapor precursor to form a vapor mixture; and
depositing the vapor mixture onto a substrate using pulsed plasma enhanced chemical vapor deposition to produce the metal chalcogenide coated substrate.

9. The method of claim 8, wherein the vapor phase metal precursor is at least one of a metal carbonyl and a metal hexafluoride.

10. The method of claim 8, wherein the chalcogen vapor precursor comprises a chalcogen selected from the group consisting of a sulfur, a selenium, a tellurium, a polonium and combinations thereof.

11. The method of claim 8, wherein a frequency of the pulsed plasma enhanced chemical vapor deposition is between about 0.1 Hz and about 10 Hz.

12. The method of claim 8, wherein the vapor mixture is deposited at a thickness of between about 0.01 nm to about 0.5 nm for each pulse using the pulsed plasma enhanced chemical vapor deposition.

13. The method of claim 8, wherein the vapor mixture is deposited onto the substrate at a deposition temperature between about 200° C. and about 400° C.

14. The method of claim 8, wherein the ratio of the metal precursor to the chalcogen vapor precursor of the mixture is between about 1: about 10 and about 1: about 100.

15. The method of claim 8, wherein an excess of the chalcogen vapor precursor is in the vapor mixture.

16. A metal chalcogenide coated substrate, comprising:
a substrate; and
a thin film coating comprising a metal dichalcogenide, wherein the thin film coating has a chalcogen atom to metal atom ratio of between about 1.9:1 and about 2.0:1.

17. The metal chalcogenide coated substrate of claim 16, wherein the metal dichalcogenide is one or more of a molybdenum dichalcogenide, an iron dichalcogenide, a tungsten dichalcogenide, a titanium dichalcogenide, and a niobium dichalcogenide.

18. The metal chalcogenide coated substrate of claim 16, wherein the metal dichalcogenide is one or more of a disulfide, a diselenide, a ditelluride, and a dipolonide.

19. The metal chalcogenide coated substrate of claim 16, wherein a thickness of the thin film coating is between about 1 nm and about 200 nm.

20. The metal chalcogenide coated substrate of claim 16, wherein the substrate is at least one of a glass, a metal, and a polymer.
